(19) United States
(12) Patent Application Publication
(10) Pub. No.: US 2024/0332177 A1
(43) Pub. Date: Oct. 3, 2024

(54) THREE-DIMENSIONAL MEMORY DEVICE CONTAINING MEMORY OPENINGS ARRANGED IN NON-EQUILATERAL TRIANGULAR LAYOUT AND METHOD OF MAKING THEREOF

(71) Applicant: SANDISK TECHNOLOGIES LLC, ADDISON, TX (US)

(72) Inventors: Ryo NAKAMURA, Yokkaichi (JP); Fei ZHOU, San Jose, CA (US); Rahul SHARANGPANI, Fremont, CA (US); Adarsh RAJASHEKHAR, Santa Clara, CA (US); Raghuveer S. MAKALA, Campbell, CA (US)

(21) Appl. No.: 18/362,706

(22) Filed: Jul. 31, 2023

Related U.S. Application Data
(60) Provisional application No. 63/493,149, filed on Mar. 30, 2023.

(51) Int. Cl. H01L 23/528; G11C 16/04; H01L 23/522; H10B 41/10; H10B 41/27; H10B 41/35; H10B 43/10; H10B 43/27; H10B 43/35

(52) U.S. Cl. CPC H01L 23/5283; G11C 16/0483; H01L 23/5226; H10B 41/10; H10B 41/27; H10B 41/35; H10B 43/10; H10B 43/27; H10B 43/35

(57) ABSTRACT

A memory device includes an alternating stack of insulating layers and electrically conductive layers, memory openings vertically extending through the alternating stack, where a smallest unit shape of three nearest neighbor memory openings is a non-equilateral triangle, and memory opening fill structures located in the memory openings, where each of the memory opening fill structures includes a vertical semiconductor channel and a vertical stack of memory elements.

### FIELD

The present disclosure relates generally to the field of semiconductor devices, and particularly to a three-dimensional memory device including memory openings arranged in a non-equilateral triangular layout and methods of manufacturing the same.

### BACKGROUND

Three-dimensional vertical NAND strings having one bit per cell are disclosed in an article by T. Endoh et al., titled “Novel Ultra High-Density Memory With A Stacked-Surrounding Gate Transistor (S-SGT) Structured Cell”, IEDM Proc. (2001) 33-36.

### SUMMARY

According to an aspect of the present disclosure, a memory device includes an alternating stack of insulating layers and electrically conductive layers, memory openings vertically extending through the alternating stack, where a smallest unit shape of three nearest neighbor memory openings is a non-equilateral triangle, and memory opening fill structures located in the memory openings, where each of the memory opening fill structures includes a vertical semiconductor channel and a vertical stack of memory elements.

According to another aspect of the present disclosure, a memory device includes an alternating stack of insulating layers and electrically conductive layers, memory openings vertically extending through the alternating stack, wherein each of the memory openings has a respective elongated horizontal cross-sectional shape having a respective a major axis and a respective minor axis, and the major axes of the memory openings extend in a nearest neighbor memory opening direction; and memory opening fill structures located in the memory openings, wherein each of the memory opening fill structures comprises a vertical semiconductor channel and a vertical stack of memory elements.

According to yet another aspect of the present disclosure, a method of forming a memory device comprises forming an alternating stack of insulating layers and sacrificial material layers over a substrate; forming memory openings vertically extending through the alternating stack, wherein a smallest unit shape of three nearest neighbor memory openings is a non-equilateral triangle; forming memory opening fill structures located in the memory openings, wherein each of the memory opening fill structures comprises a respective vertical stack of memory elements and vertical semiconductor channels; removing the sacrificial material layers from between the memory opening fill structures to form laterally-extending cavities; and forming electrically conductive layers in the laterally extending cavities.

### BRIEF DESCRIPTION OF THE DRAWINGS

FIG. 1 is a schematic vertical cross-sectional view of an exemplary structure after formation of optional semiconductor devices, optional lower-level metal interconnect structures, a semiconductor material layer, and an alternating stack of insulating layers and sacrificial material layers according to an embodiment of the present disclosure.

FIG. 2 is a schematic vertical cross-sectional view of the exemplary structure after formation of stepped terraces and a retro-stepped dielectric material portion according to an embodiment of the present disclosure.

FIG. 3A is a schematic vertical cross-sectional view of the exemplary structure after formation of memory openings and support openings according to an embodiment of the present disclosure.

FIG. 3B is a top-down view of the exemplary structure of FIG. 3A. The vertical plane A-A′ is the plane of the cross-section for FIG. 3A.

FIGS. 4A-4I are magnified top-down views of various configurations of a portion of a memory array region after the processing steps of FIGS. 3A and 3B.

FIG. 5 is a vertical cross-sectional view of the exemplary structure after formation of support pillar structures according to an embodiment of the present disclosure.

FIGS. 6A-6D are sequential schematic vertical cross-sectional views of a memory opening within the exemplary structure during formation of a memory opening fill structure according to an embodiment of the present disclosure.

FIG. 7 is a schematic vertical cross-sectional view of the exemplary structure after formation of memory opening fill structures and support pillar structures according to an embodiment of the present disclosure.

FIG. 8A is a schematic vertical cross-sectional view of the exemplary structure after formation of a contact-level dielectric layer, lateral isolation trenches, and source regions according to an embodiment of the present disclosure.

FIG. 8B is a partial see-through top-down view of the exemplary structure of FIG. 8A. The vertical plane A-A′ is the plane of the schematic vertical cross-sectional view of FIG. 8A.

FIG. 9 is a vertical cross-sectional view of the exemplary structure after formation of a source-level cavity according to an embodiment of the present disclosure.

FIG. 10 is a vertical cross-sectional view of the exemplary structure after formation of a source contact layer according to an embodiment of the present disclosure.

FIG. 11 is a vertical cross-sectional view of the exemplary structure after formation of laterally-extending cavities according to an embodiment of the present disclosure.

FIG. 12 is a vertical cross-sectional view of the exemplary structure after formation of electrically conductive layers according to an embodiment of the present disclosure.

FIG. 13A is a vertical cross-sectional view of the exemplary structure after formation of lateral isolation trench fill structures and contact via structures according to an embodiment of the present disclosure.

FIG. 13B is a top-down view of the exemplary structure of FIG. 13A. The vertical plane A-A′ is the cut plane of the vertical cross-sectional view of FIG. 13A.

FIG. 14A is a vertical cross-sectional view of the exemplary structure after formation of connection via structures and bit-line-level metal lines according to an embodiment of the present disclosure.

FIG. 14B is a top-down view of the exemplary structure of FIG. 14A. The vertical plane A-A′ is the cut plane of the vertical cross-sectional view of FIG. 14A.

FIG. 15 is a vertical cross-sectional view of the exemplary structure after formation of a memory die including memory-side dielectric material layers and memory-side metal interconnect structures according to an embodiment of the present disclosure.

FIG. 16 is a vertical cross-sectional view of a logic die according to an embodiment of the present disclosure.

FIG. 17 is a vertical cross-sectional view of the exemplary structure after attaching the logic die to the memory die according to an embodiment of the present disclosure.

FIG. 18 is a vertical cross-sectional view of the exemplary structure after removal of the carrier substrate according to an embodiment of the present disclosure.

### DETAILED DESCRIPTION

As discussed above, embodiments of the present disclosure are directed to a three-dimensional memory device including memory openings arranged in a non-equilateral triangular layout for facilitating lateral diffusion of a reactant during formation of replacement word lines and methods of manufacturing the same, the various aspects of which are described below. In one embodiment, the memory openings may be elongated along the nearest neighbor distance.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an element is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

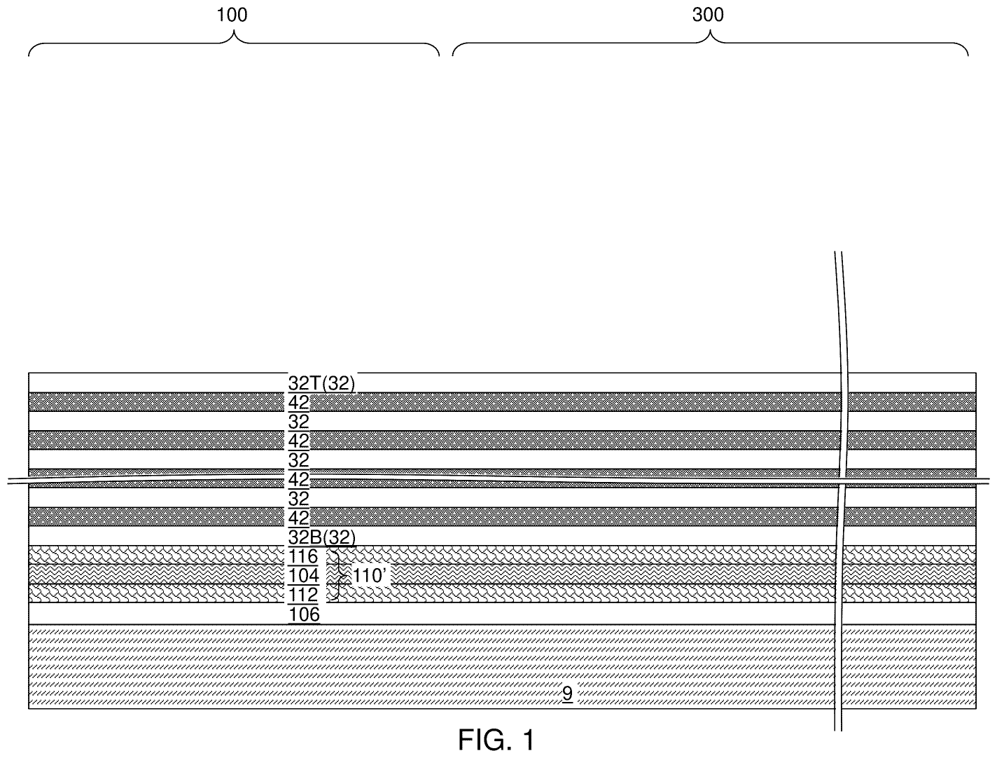

Referring to FIG. 1, an exemplary structure according to an embodiment of the present disclosure is illustrated. The exemplary structure comprises a substrate 9, which may be a semiconductor substrate or a conductive substrate. For example, the substrate 9 may comprise a commercially available silicon wafer. Alternatively, the substrate 9 may comprise a carrier substrate 9 which is formed of any material that may be removed selective the materials of insulating layers 32 and dielectric material portions to be subsequently formed.

An optional insulating material layer can be formed on a top surface of the carrier substrate 9. The insulating material layer can be subsequently employed as a stopping material layer for a process that removes the carrier substrate 9, and is herein referred to as a stopper insulating layer 106, or as a backside pad dielectric layer. If a polishing process such as a chemical mechanical polishing process is employed to subsequently remove the carrier substrate 9, the stopper material layer 106 may be subsequently employed as a polishing stopper material layer. If an etch process such as a wet etch process is employed to subsequently remove the carrier substrate 9, the stopper material layer 106 may be subsequently employed as an etch stop material layer. In one embodiment, the stopper insulating layer 106 comprises a dielectric material such as undoped silicate glass, a doped silicate glass, or silicon nitride. The thickness of the stopper insulating layer 106 may be in a range from 50 nm to 600 nm, such as from 100 nm to 300 nm, although lesser and greater thicknesses may also be employed.

Optional in-process source-level material layers 110′ can be formed over the stopper insulating layer 106. The in-process source-level material layers 110′ may include various layers that are subsequently modified to form source-level material layers. The source-level material layers, upon formation, include a source contact layer that functions as a common source region for vertical field effect transistors of a three-dimensional memory device. In one embodiment, the in-process source-level material layers 110′ may include, from bottom to top, a lower source-level semiconductor layer 112, an optional lower sacrificial liner 103, a source-level sacrificial layer 104, an optional upper sacrificial liner 105, and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. The thickness of each of the lower source-level semiconductor layer 112 and the upper source-level semiconductor layer 116 may be in a range from 10 nm to 300 nm, such as from 20 nm to 150 nm, although lesser and greater thicknesses may also be used.

The source-level sacrificial layer 104 includes a sacrificial material that may be removed selective to the lower sacrificial liner 103 (or selective to the lower source-level semiconductor layer 112) and the upper sacrificial liner 105 (or selective to the upper source-level semiconductor layer 116). In one embodiment, the source-level sacrificial layer 104 may include a semiconductor material such as undoped amorphous silicon or a silicon-germanium alloy with an atomic concentration of germanium greater than 20%. The thickness of the source-level sacrificial layer 104 may be in a range from 30 nm to 400 nm, such as from 60 nm to 200 nm, although lesser and greater thicknesses may also be used. The lower sacrificial liner 103 (if present) and the upper sacrificial liner 105 (if present) include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, each of the lower sacrificial liner 103 and the upper sacrificial liner 105 may include a silicon oxide layer having a thickness in a range from 2 nm to 30 nm, although lesser and greater thicknesses may also be used.

An alternating stack of first material layers and second material layers can be formed over the in-process source-level material layers 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the carrier substrate 9 is herein referred to as a bottommost insulating layer 32B.

Each of the insulating layers 32 other than the topmost insulating layer 32 may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32 may have a thickness of about one half of the thickness of other insulating layers 32.

The exemplary structure comprises a memory array region 100 in which a three-dimensional array of memory elements is to be subsequently formed, and a contact region 300 in which layer contact via structures contacting word lines are to be subsequently formed.

While an embodiment is described in which the spacer material layers are formed as sacrificial material layers 42, the spacer material layers may be formed as electrically conductive layers in an alternative embodiment. Generally, spacer material layers of the present disclosure may be formed as, or may be subsequently replaced at least partly with, electrically conductive layers.

In an alternative embodiment, driver circuit semiconductor devices (e.g., transistors) may be formed over the substrate 9 next to the alternating stack (32, 42) or underneath the alternating stack (32, 42). In yet another alternative embodiment, the in-process source-level material layers 110′ may be omitted, in case the substrate 9 is a carrier substrate which is later removed and a top source contact layer is formed on an exposed surface of the memory device.

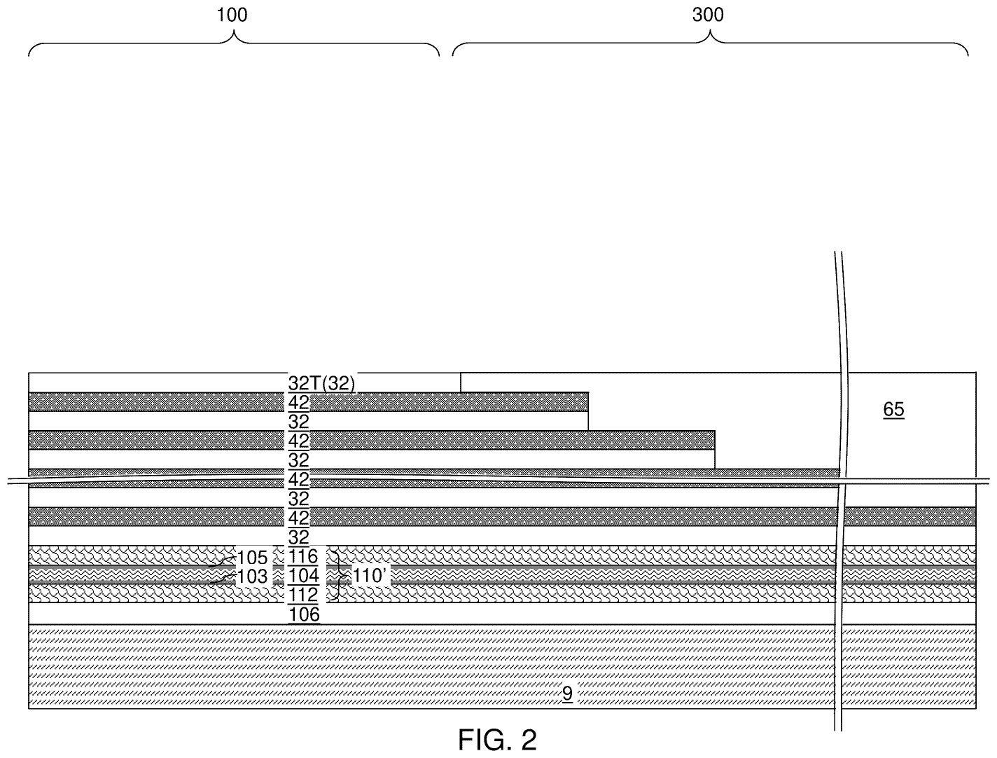

Referring to FIG. 2, optional stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer 32B) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

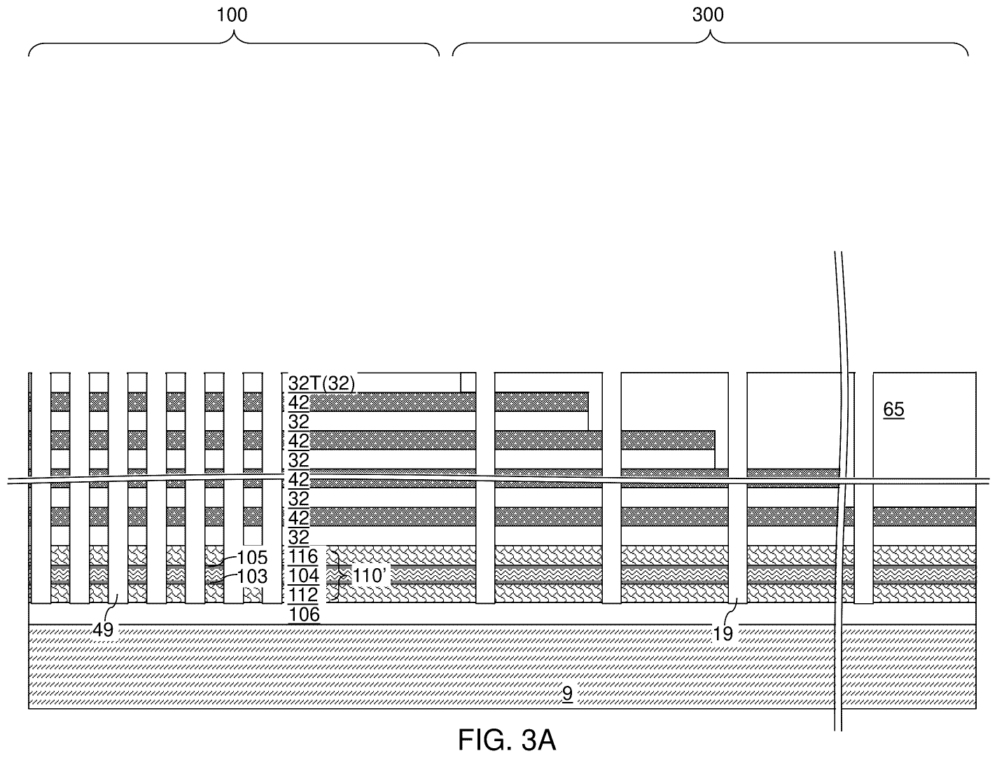

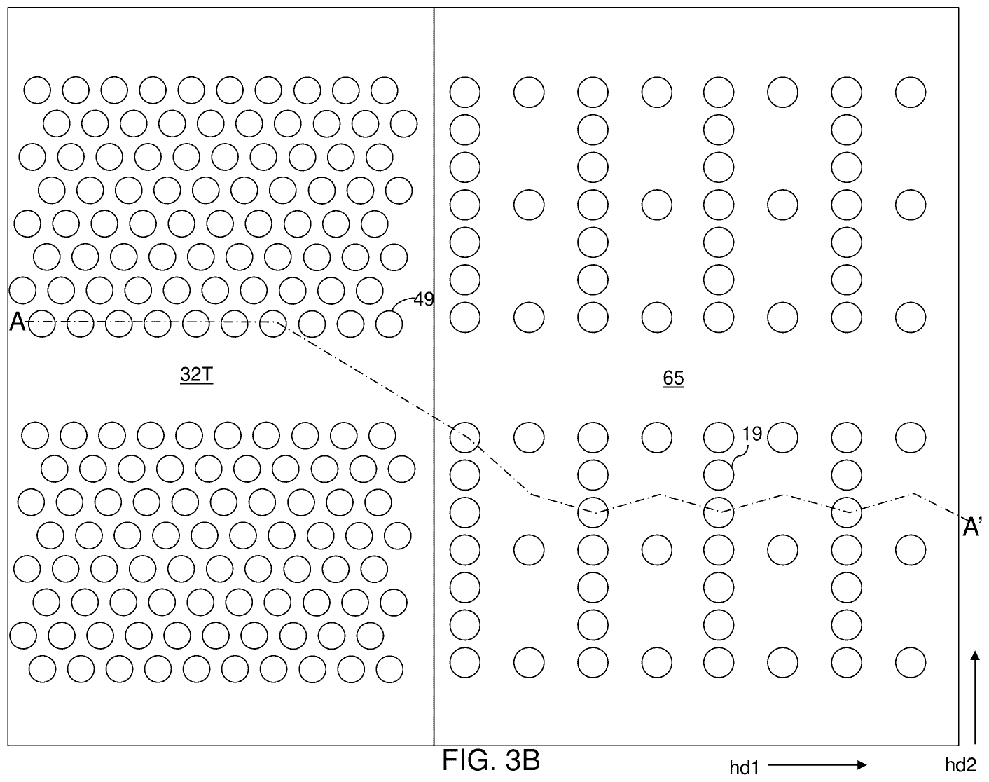

Referring to FIGS. 3A and 3B, an etch mask layer (not shown) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can vertically extend through the alternating stack (32, 42) and into the in-process source-level material layers 110′ In one embodiment, bottom surfaces of the memory openings 49 and the support openings 19 may be formed within the lower source-level semiconductor layer 112 or at an interface between the lower source-level semiconductor layer and the stopper insulating layer 106.

The support openings 19 may have a diameter in a range from 60 nm too 400 nm, such as from 120 nm to 300 nm, although lesser and greater thicknesses may be employed. The memory openings 49 may have a diameter in a range from 60 nm too 400 nm, such as from 120 nm to 300 nm, although lesser and greater thicknesses may be employed.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2.

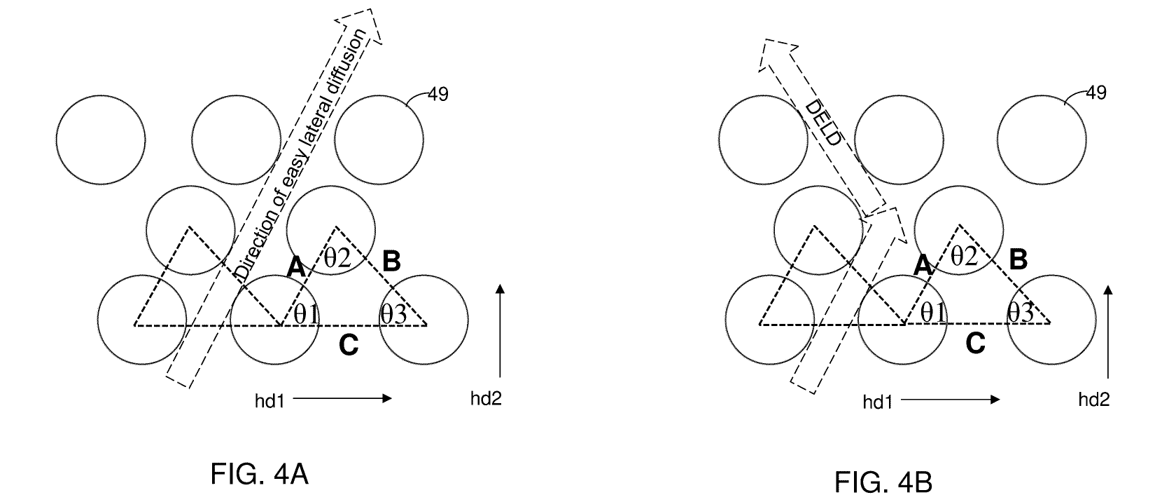

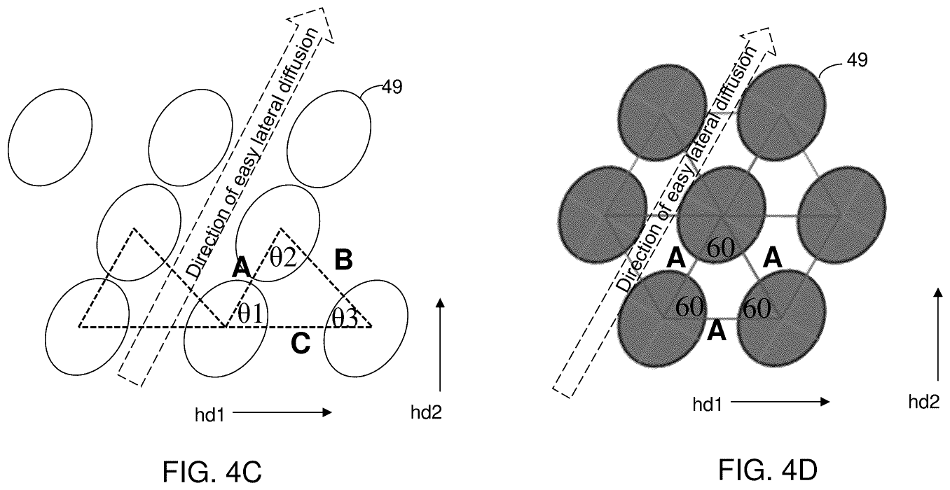

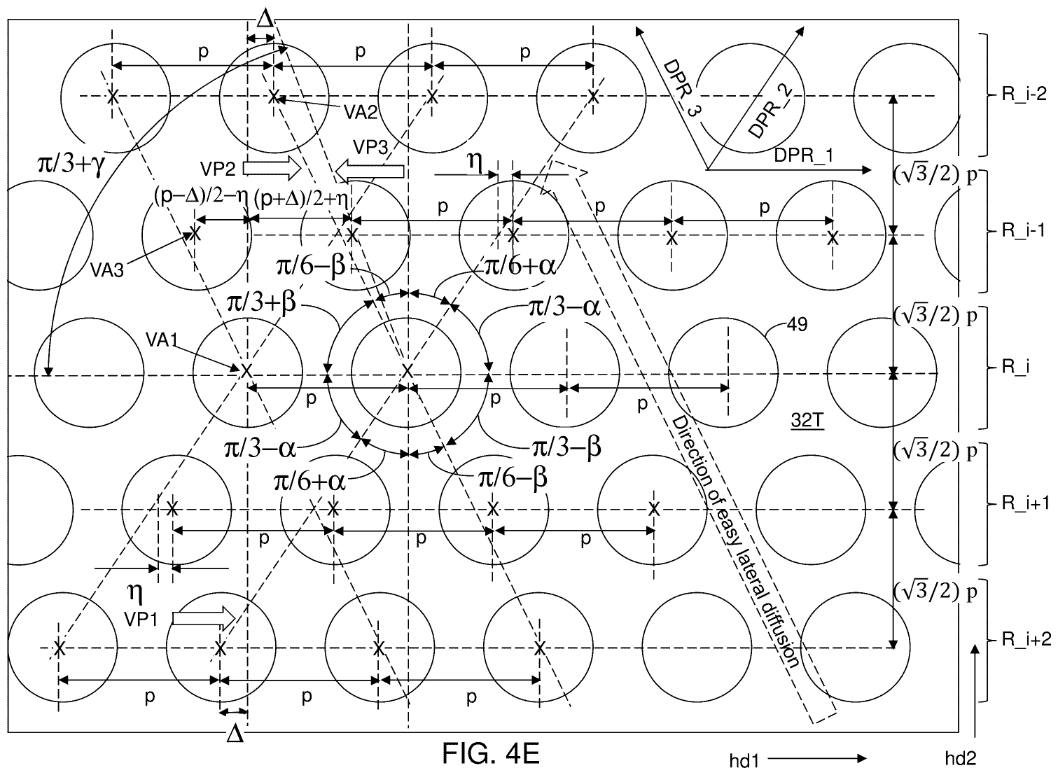

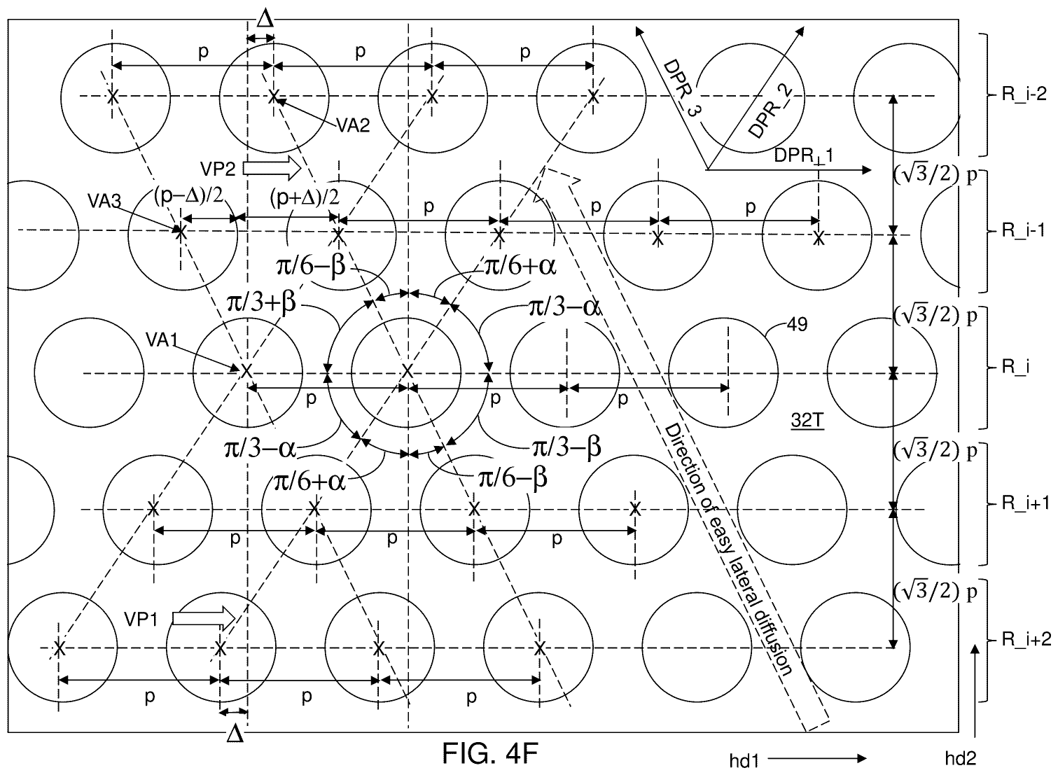

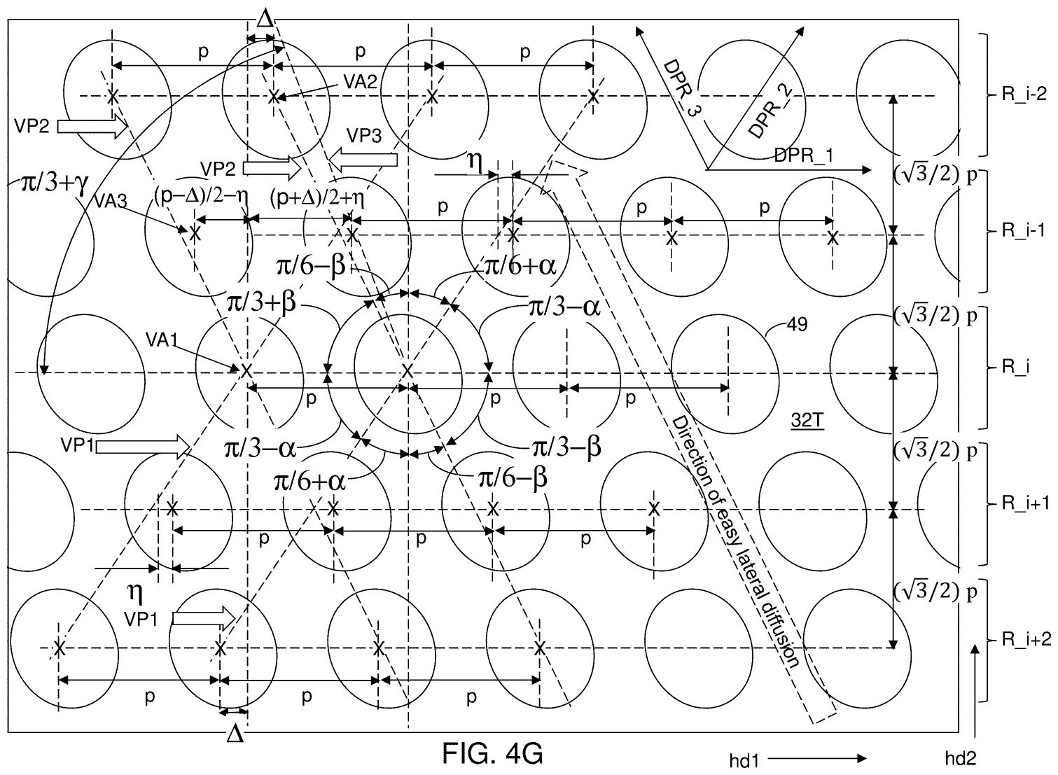

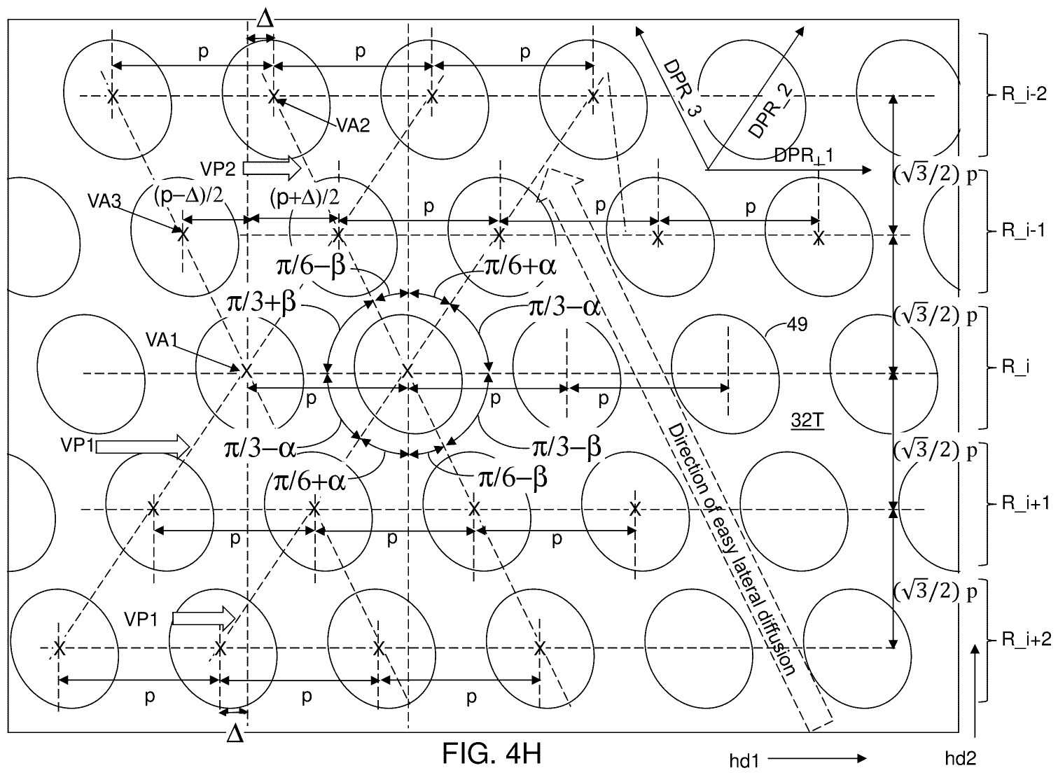

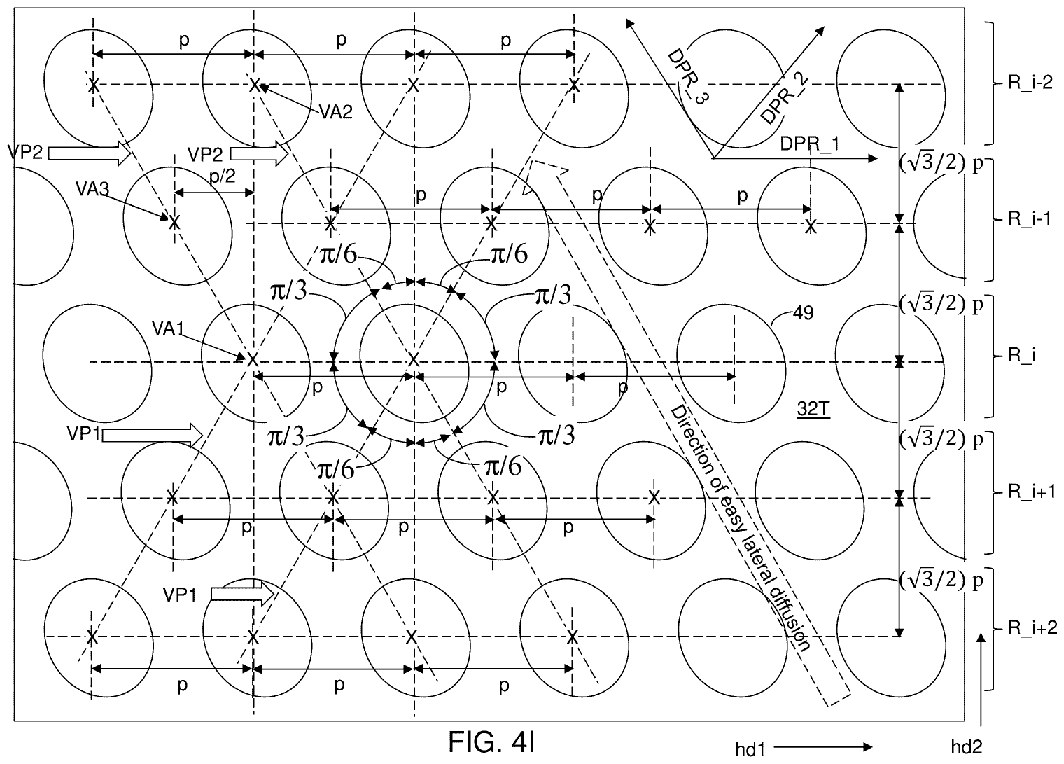

FIGS. 4A-4I are magnified top-down views of various configurations of a portion of a memory array region 100 after the processing steps of FIGS. 3A and 3B.

Referring to FIG. 4A, a portion of the memory array region 100 is shown after the processing steps of FIGS. 3A and 3B according to a first embodiment. In the first embodiment, each memory opening 49 within the multiple rows of memory openings 49 has a respective circular horizontal cross-sectional shape. As used herein, “circular” includes exactly circular shapes or slightly off circular shapes due to lithography and etching deviations.

The smallest unit shape of three nearest neighbor memory openings 49 is a non-equilateral triangle. In one embodiment, the non-equilateral triangle comprises a scalene triangle having three sides A, B and C which do not equal to each other (i.e., A≠B≠C) and three angles θ1, θ2 and θ3 which do not equal to each other (i.e., θ1≠θ≠θ3). The vertices of the scalene triangle are located at the geometric centers of the three memory openings 49 in a horizontal plane. In this configuration of memory opening, there exists a direction providing a greater average lateral distance between neighboring pairs of memory openings 49. This horizontal direction is labeled as “direction of easy lateral diffusion,” and provides a wider diffusion path during subsequent processing steps that are employed to isotropically etch the sacrificial material layers 42 to form laterally-extending cavities, and to conformally deposit at least one conductive material to form electrically conductive layers. Thus, the direction of easy lateral diffusion comprises a first diffusion path is provided in the laterally-extending cavities between a first set of memory openings 49 which is wider than a second diffusion path provided in the laterally extending cavities between a second set of memory openings. Thus, improved electrically conductive layer filling may be achieved. Such paths also provide enhanced fluorine out diffusion paths if fluorine is used to deposit the electrically conductive layers (e.g., if WF₆ is used to deposit tungsten electrically conductive layers). Thus, less fluorine becomes trapped in the device, which improves device reliability because trapped fluorine may damage various device layers due to solid state diffusion between device layers.

Referring to FIG. 4B, a portion of the memory array region 100 is shown after the processing steps of FIGS. 3A and 3B according to a second embodiment. In the second embodiment, the memory openings 49 are arranged in a zig-zag configuration. The smallest unit shape of three nearest neighbor memory openings 49 is still a non-equilateral triangle, such as a scalene triangle. However, in this configuration, the direction of easy lateral diffusion (DELD) is a zig-zag horizontal direction.

Referring to FIG. 4C, a portion of the memory array region 100 is shown after the processing steps of FIGS. 3A and 3B according to a third embodiment. In the third embodiment, the memory openings 49 have non-circular horizontal cross-sectional shapes. For example, the memory openings may have oval horizontal cross-sectional shapes having a long axis and a short axis. The long axes extend along the nearest neighbor memory opening direction, such as the DELD direction. The smallest unit shape of three nearest neighbor memory openings 49 is still a non-equilateral triangle, such as a scalene triangle.

Referring to FIG. 4D, a portion of the memory array region 100 is shown after the processing steps of FIGS. 3A and 3B according to the fourth embodiment. In the fourth embodiment, the memory openings 49 have non-circular, such as oval, horizontal cross-sectional shapes. The smallest unit shape of three nearest neighbor memory openings 49 is an equilateral triangle, having all three sides “A” equal to each other and all three angles equal to 60 degrees. Thus, in this configuration, the memory openings 49 are arranged in a hexagonal close packed lattice.

FIGS. 4E to 4I illustrate additional geometric features of the memory opening 49 layouts of the various embodiments of the present disclosure.

Referring to FIG. 4E, a first configuration of a portion of the memory array region 100 is shown after the processing steps of FIGS. 3A and 3B. In the first configuration, each memory opening 49 within the multiple rows of memory openings 49 has a respective circular horizontal cross-sectional shape.

According to an aspect of the present disclosure, multiple rows of memory openings 49 can be formed through the alternating stack (32, 42) in each cluster of memory openings 49. Each row among the multiple rows comprises a respective one-dimensional periodic array of memory openings 49 having a uniform pitch p along the first horizontal direction hd1. The multiple rows are laterally spaced from each other along the second horizontal direction hd2, which is perpendicular to the first horizontal direction hd1.

Upon sequentially numbering the multiple rows of memory openings 49 in any cluster of memory openings 49 with integers beginning with 1 along the second horizontal direction hd2, the multiple rows of memory openings 49 comprise odd-numbered rows and even-numbered rows. For each memory opening 49, a respective geometrical center can be defined as the center of gravity of a hypothetical object having a same volume (i.e., occupying the same space) as the memory opening 49 and having a uniform density throughout. Further, for each memory opening 49, a respective vertical axis passing through the geometrical center can be defined. Each vertical axis passing through the geometrical center of a respective memory opening 49 is perpendicular to the top surface of the carrier substrate 9 and/or to the bottommost surface of the alternating stack (32, 42).

In the illustrated example, five rows of memory openings 49 are illustrated, which comprise an (i−2)-th row (labeled “R_i−2”), an (i−1)-th row (labeled “R_i−1”), an i-th row (labeled “R_i”), an (i+1)-th row (labeled “R_i+1”), and an (i+2)-th row (labeled “R_i+2). If R is an odd number, the (i−2)-th row, the i-th row, and the (i+2)-th row are odd-numbered rows, and the (i−1)-th row and the (i+1)-th row are even-numbered rows. In one embodiment, the center-to-center distance between neighboring rows of memory openings 49 may be √3/2 times the uniform pitch p. In another embodiment, center-to-center distance between neighboring rows of memory openings 49 may be different from √3/2 times the uniform pitch p, and may be in a range from 0.85 times √3/2 times the uniform pitch p to 1.15 times √3/2 times the uniform pitch p, and/or in a range from 0.90 times √3/2 times the uniform pitch p to 1.10 times √3/2 times the uniform pitch p, and/or in a range from 0.95 times √3/2 times the uniform pitch p to 1.05 times √3/2 times the uniform pitch p.

Generally, the pattern of the memory openings 49 may have three directions of periodic repetitions. The first direction of periodic repetition DPR_1 can be the first horizontal direction hd1, and the pattern of the memory openings 49 may repeat along the first direction of periodic repetition DPR_1 with the uniform pitch p, which is the center-to-center distance between geometrical centers of a neighboring pair of memory openings 49 within any row of memory openings 49. The second direction of periodic repetition DPR_2 can be rotated along a first rotation direction (which may be anticlockwise or clockwise) from the first direction of periodic repetition DPR_1 by an angle π/3−α, which is less than π/3. The pattern of the memory openings 49 may be repeated at every other row along the second direction of periodic repetition DPR_2. The third direction of periodic repetition DPR_3 can be rotated along a second rotation direction (which is the opposite direction of the first rotation direction) from the opposite direction of the first direction of periodic repetition DPR_1 by an angle π/3+β, which is greater than π/3. The pattern of the memory openings 49 may be repeated at every other row along the third direction of periodic repetition DPR_3.

According to an aspect of the present disclosure, for each first vertical axis VA1 passing through a geometrical center of a respective memory opening 49 in any odd-numbered row, a second vertical axis VA2 passing through a geometrical center of a most proximal memory opening 49 within a most proximal odd-numbered row is laterally offset from the first vertical axis VA1 along the first horizontal direction hd1 by a first lateral offset distance Δ that is greater than 0 and is less than one half of the uniform pitch p. In one embodiment, the first lateral offset distance Δ may be greater than 0.01 times the uniform pitch p, and/or may be in a range from 0.02 times the uniform pitch p, and/or may be in a range from 0.03 times the uniform pitch p, and/or may be in a range from 0.05 times the uniform pitch p, and/or may be in a range from 0.10 times the uniform pitch p, and/or may be in a range from 0.15 times the uniform pitch p, and/or may be in a range from 0.20 times the uniform pitch p, and/or may be in a range from 0.25 times the uniform pitch p, and/or may be in a range from 0.30 times the uniform pitch p, and/or may be in a range from 0.35 times the uniform pitch p, and/or may be in a range from 0.40 times the uniform pitch p. Further, the first lateral offset distance Δ may be less than 0.49 times the uniform pitch p, and/or may be in a range from 0.48 times the uniform pitch p, and/or may be in a range from 0.47 times the uniform pitch p, and/or may be in a range from 0.45 times the uniform pitch p, and/or may be in a range from 0.40 times the uniform pitch p, and/or may be in a range from 0.35 times the uniform pitch p, and/or may be in a range from 0.30 times the uniform pitch p, and/or may be in a range from 0.25 times the uniform pitch p, and/or may be in a range from 0.20 times the uniform pitch p, and/or may be in a range from 0.15 times the uniform pitch p, and/or may be in a range from 0.10 times the uniform pitch p.

In one embodiment, for each first vertical axis VA1 passing through the geometrical center of the respective memory opening 49 in any odd-numbered row, a third vertical axis VA3 passing through a geometrical center of a most proximal memory opening 49 within a most proximal even-numbered row is laterally offset from the first vertical axis VA1 along the first horizontal direction hd1 by a second lateral offset distance (p−Δ)/2−η that is greater than 0 and is less than (p−Δ)/2. In this case, the periodicity of the pattern of the memory openings 49 along the second horizontal direction hd2 is greater than the center-to-center distance between neighboring pairs of rows, and may be the same as twice the center-to-center distance between neighboring pairs of rows.

In one embodiment, the difference between (p−Δ)/2 and the second lateral offset distance (p−Δ)/2−η is a lateral shift distance η that is greater than 0 and is less than Δ/2. In one embodiment, the lateral shift distance η may be greater than 0.05 times Δ/2, and/or may be greater than 0.1 times Δ/2, and/or may be greater than 0.2 times Δ/2, and/or may be greater than 0.3 times Δ/2, may be greater than 0.4 times Δ/2, and/or may be greater than 0.5 times Δ/2, may be greater than 0.6 times Δ/2, and/or may be greater than 0.7 times Δ/2, may be greater than 0.8 times Δ/2, and/or may be greater than 0.9 times Δ/2. Further, the lateral shift distance η may be less than 0.95 times Δ/2, and/or may be less than 0.9 times Δ/2, and/or may be less than 0.8 times Δ/2, and/or may be less than 0.7 times Δ/2, may be less than 0.6 times Δ/2, and/or may be less than 0.5 times Δ/2, may be less than 0.4 times Δ/2, and/or may be less than 0.3 times Δ/2, may be less than 0.2 times Δ/2, and/or may be less than 0.1 times Δ/2.

In one embodiment, for each first vertical axis VA1 passing through the geometrical center of the respective memory opening 49 in any odd-numbered row, a planar vertical plane that passes through the first vertical axis VA1 and is parallel to the second horizontal direction hd2 does not pass through a geometrical center of any memory opening 49 within any nearest-neighboring row of memory openings 49 or within any second-nearest-neighboring row of memory openings 49.

In one embodiment, a first vertical plane VP1 passing through a geometrical center of a memory opening 49 within an odd-numbered row of memory openings 49 and passing through a geometrical center of a memory opening 49 within a nearest-neighboring odd-numbered row of memory openings 49 is at a first angle (π/3−α) with respective to the first horizontal direction hd1. The first vertical plane VP1 can be parallel to the second direction of periodic repetition DPR_2. The first angle (π/3−α) is less than π/3 and is greater than arctan(\sqrt{3}/(1.5)). In case the center-to-center distance between neighboring rows of memory openings 49 is √3/2 times the uniform pitch p, the lateral offset distance along the first horizontal direction between the geometrical center of the memory opening 49 within the odd-numbered row of memory openings 49 and the geometrical center of a memory opening 49 within the nearest-neighboring odd-numbered row of memory openings 49 is greater than p, and is less than 1.5 times p. In the present disclosure, all angles are measured in radians.

In one embodiment, a second vertical plane VP2 passing through the geometrical center of the memory opening 49 within the odd-numbered row of memory openings 49 and passing through a geometrical center of another memory opening 49 within the nearest-neighboring odd-numbered row of memory openings 49 is at a second angle (π/3+β) with respective to the first horizontal direction hd1. The second angle (π/3+β) is greater than π/3 and is less than arctan(\sqrt{3}/(1.5)). The second vertical plane VP2 can be parallel to the third direction of periodic repetition DPR_3.

In one embodiment, a third vertical plane VP3 passing through the geometrical center of the memory opening 49 within the odd-numbered row of memory openings 49 and passing through a geometrical center of a memory opening 49 a nearest-neighboring even-numbered row of memory openings 49 is at a third angle (π/3+γ) with respective to the first horizontal direction hd1. The third angle (π/3+γ) is greater than the second angle (π/3+β).

The first configuration of the array of memory openings 49 provides a horizontal direction providing a greater average lateral distance between neighboring pairs of memory openings 49. This horizontal direction is labeled as “direction of easy lateral diffusion,” and provides high-diffusivity diffusion paths during subsequent processing steps that are employed to isotropically etch the sacrificial material layers 42 to form laterally-extending cavities, and to conformally deposit at least one conductive material to form electrically conductive layers. In the illustrated example, the “direction of easy lateral diffusion” may be parallel to the third direction of periodic repetition DPR_3.

Referring to FIG. 4F, a second configuration of a portion of the memory array region 100 is shown after the processing steps of FIGS. 3A and 3B. In the second configuration, each memory opening 49 within the multiple rows of memory openings 49 has a respective circular horizontal cross-sectional shape. The second configuration of the memory openings 49 can be derived from the first configuration of the memory openings 49 illustrated in FIG. 4A by setting the value of the parameter η to be equal to zero. Further, the value of the parameter γ can be the same as the value of β in the second configuration. In the second configuration, for each first vertical axis VA1 passing through the geometrical center of the respective memory opening 49 in any odd-numbered row, a third vertical axis VA3 passing through a geometrical center of a most proximal memory opening 49 within a most proximal even-numbered row is laterally offset from the first vertical axis VA1 along the first horizontal direction hd1 by a second lateral offset distance that equals p/2.

In the second configuration, the pattern of the memory openings 49 may have three directions of periodic repetitions. The first direction of periodic repetition DPR_1 can be the first horizontal direction hd1, and the pattern of the memory openings 49 may repeat along the first direction of periodic repetition DPR_1 with the uniform pitch p, which is the center-to-center distance between geometrical centers of a neighboring pair of memory openings 49 within any row of memory openings 49. The second direction of periodic repetition DPR_2 can be rotated along a first rotation direction (which may be anticlockwise or clockwise) from the first direction of periodic repetition DPR_1 by an angle π/3−α, which is less than π/3. The pattern of the memory openings 49 may be repeated at every row along the second direction of periodic repetition DPR_2. Thus, the repetition distance along the second direction of periodic repetition DPR_2 is halved in the second configuration compared to the repetition distance in the first configuration. The third direction of periodic repetition DPR_3 can be rotated along a second rotation direction (which is the opposite direction of the first rotation direction) from the opposite direction of the first direction of periodic repetition DPR_1 by an angle π/3+β, which is greater than π/3. The pattern of the memory openings 49 may be repeated at every row along the third direction of periodic repetition DPR_3. Thus, the repetition distance along the third direction of periodic repetition DPR_3 is halved in the second configuration compared to the repetition distance in the first configuration.

The second configuration of the array of memory openings 49 provides a horizontal direction providing a greater average lateral distance between neighboring pairs of memory openings 49. This horizontal direction is labeled as “direction of easy lateral diffusion,” and provides high-diffusivity diffusion paths during subsequent processing steps that are employed to isotropically etch the sacrificial material layers 42 to form laterally-extending cavities, and to conformally deposit at least one conductive material to form electrically conductive layers. In the illustrated example, the “direction of easy lateral diffusion” may be parallel to the third direction of periodic repetition DPR_3.

Referring to FIG. 4G, a third configuration of a portion of the memory array region 100 is shown after the processing steps of FIGS. 3A and 3B. In the third configuration, each memory opening 49 within the multiple rows of memory openings 49 has a respective non-circular horizontal cross-sectional shape, which may be an elliptical shape. In other words, the third configuration of the memory openings 49 can be derived from the first configuration of the memory openings 49 illustrated in FIG. 4A by elongating each of the memory openings 49 along a horizontal direction in a manner that generates a horizontal direction providing a greater average lateral distance between neighboring pairs of memory openings 49.

In the illustrated example, the elongation direction of the memory openings 49 may be parallel to the “direction of easy lateral diffusion” discussed with reference to FIG. 4A. By selecting the elongation direction of the memory openings 49 to be parallel to the “direction of easy lateral diffusion,” the diffusion paths that are parallel to the “direction of easy lateral diffusion” can provide high-diffusivity diffusion paths during subsequent processing steps that are employed to isotropically etch the sacrificial material layers 42 to form laterally-extending cavities, and to conformally deposit at least one conductive material to form electrically conductive layers. In the illustrated example, the “direction of easy lateral diffusion” may be parallel to the third direction of periodic repetition DPR_3.

In the third configuration of the array of memory openings 49, multiple rows of memory openings 49 vertically extend through the alternating stack (32, 42). Each row among the multiple rows comprises a respective one-dimensional periodic array of memory openings 49 having a uniform pitch p along the first horizontal direction hd1. The multiple rows are laterally spaced among one another along the second horizontal direction hd2 that is perpendicular to the first horizontal direction hd1. Each memory opening 49 within the multiple rows of memory openings 49 has a respective elongated horizontal cross-sectional shape having a respective horizontal direction of a major axis and a respective horizontal direction of a minor axis. As used herein, the major axis of a two-dimensional shape is the maximum lateral dimension of the two-dimensional shape, and minor axis of the two-dimensional shape is the minimum lateral dimension of the two-dimensional shape. In case the two-dimensional shape if an ellipse, the major axis can be the same as the mathematical definition of the major axis of an ellipse, and the minor axis can be the same as the mathematical definition of the minor axis of the ellipse.

Each horizontal direction of the major axis of the memory openings 49 in the multiple rows of memory openings 49 can be parallel among one another, and can be at a non-zero and non-orthogonal angle with respect to the first horizontal direction hd1. In one embodiment, the non-zero and non-orthogonal angle is greater than π/3 and is less than arctan(2\sqrt{3}). In one embodiment, the horizontal direction of the major axes of the memory openings 49 may be parallel to the third direction of periodic repetition DPR3, or may along an azimuthal direction that deviates from the third direction of periodic repetition DPR3 by an angle less than π/6, and/or less than π/12, and/or less than π/24. The ellipticity e of the horizontal shape of each memory opening 49, as defined by e=(1−(b/a)²)^{1/2} in which a is the major axis and b is the minor axis, may be greater than 0 and less than 0.6 (which corresponds to b/a of 0.8). In one embodiment, the ellipticity e may be greater than 0.001, and/or greater than 0.01, and/or greater than 0.03, and/or greater than 0.1, and/or greater than 0.2, and/or greater than 0.3, and/or greater than 0.4, and/or greater than 0.5. Further, the ellipticity e may be less than 0.59, and/or less than 0.5, and/or less than 0.4, and/or less than 0.3, and/or less than 0.2, and/or less than 0.1, and/or less than 0.05, and/or less than 0.03.

In one embodiment, the multiple rows comprise, upon sequentially numbering with integers beginning with 1 along the second horizontal direction hd2, odd-numbered rows and even-numbered rows, and each pattern of memory openings 49 in any odd-numbered row is periodically repeated in every other odd-numbered row along the second horizontal direction hd2 with a periodicity that equals a center-to-center distance between neighboring pairs of odd-numbered rows within the multiple rows. In one embodiment, for each first vertical axis VA1 passing through a geometrical center of a respective memory opening 49 in any odd-numbered row, a second vertical axis VA2 passing through a geometrical center of a most proximal memory opening 49 within a most proximal odd-numbered row is laterally offset from the first vertical axis VA1 along the first horizontal direction hd1 by a first lateral offset distance Δ that is greater than 0 and is less than one half of the uniform pitch p.

Generally, the values of the various parameters α, β, γ, Δ, and η in the third configuration may be in the same range as the corresponding values of the various parameters in the first configuration.

Referring to FIG. 4H, a fourth configuration of a portion of the memory array region 100 is shown after the processing steps of FIGS. 3A and 3B. In the fourth configuration, each memory opening 49 within the multiple rows of memory openings 49 has a respective elongated horizontal cross-sectional shape. The fourth configuration of the memory openings 49 can be derived from the third configuration of the memory openings 49 illustrated in FIG. 4C by setting the value of the parameter η to be equal to zero. Further, the value of the parameter γ can be the same as the value of β in the fourth configuration. In the fourth configuration, for each first vertical axis VA1 passing through the geometrical center of the respective memory opening 49 in any odd-numbered row, a third vertical axis VA3 passing through a geometrical center of a most proximal memory opening 49 within a most proximal even-numbered row is laterally offset from the first vertical axis VA1 along the first horizontal direction hd1 by a second lateral offset distance that equals (p−Δ)/2.

In the fourth configuration, the pattern of the memory openings 49 may have three directions of periodic repetitions. The first direction of periodic repetition DPR_1 can be the first horizontal direction hd1, and the pattern of the memory openings 49 may repeat along the first direction of periodic repetition DPR_1 with the uniform pitch p, which is the center-to-center distance between geometrical centers of a neighboring pair of memory openings 49 within any row of memory openings 49. The second direction of periodic repetition DPR_2 can be rotated along a first rotation direction (which may be anticlockwise or clockwise) from the first direction of periodic repetition DPR_1 by an angle π/3−α, which is less than π/3. The pattern of the memory openings 49 may be repeated at every row along the second direction of periodic repetition DPR_2. Thus, the repetition distance along the second direction of periodic repetition DPR_2 is halved in the fourth configuration compared to the repetition distance in the third configuration. The third direction of periodic repetition DPR_3 can be rotated along a second rotation direction (which is the opposite direction of the first rotation direction) from the opposite direction of the first direction of periodic repetition DPR_1 by an angle π/3+β, which is greater than π/3. The pattern of the memory openings 49 may be repeated at every row along the third direction of periodic repetition DPR_3. Thus, the repetition distance along the third direction of periodic repetition DPR_3 is halved in the fourth configuration compared to the repetition distance in the third configuration.

The fourth configuration of the array of memory openings 49 provides a horizontal direction providing a greater average lateral distance between neighboring pairs of memory openings 49. This horizontal direction is labeled as “direction of easy lateral diffusion,” and provides high-diffusivity diffusion paths during subsequent processing steps that are employed to isotropically etch the sacrificial material layers 42 to form laterally-extending cavities, and to conformally deposit at least one conductive material to form electrically conductive layers. In the illustrated example, the “direction of easy lateral diffusion” may be parallel to the third direction of periodic repetition DPR_3.

Referring to FIG. 4I, a fifth configuration of a portion of the memory array region 100 is shown after the processing steps of FIGS. 3A and 3B. In the fifth configuration, each memory opening 49 within the multiple rows of memory openings 49 has a respective elongated horizontal cross-sectional shape. The fifth configuration of the memory openings 49 can be derived from the fourth configuration of the memory openings 49 illustrated in FIG. 4C by setting the value of the parameter Δ to be equal to zero. Further, the value of the parameter γ can be the same as the value of β in the fifth configuration. In the fifth configuration, for each first vertical axis VA1 passing through the geometrical center of the respective memory opening 49 in any odd-numbered row, a fourth vertical axis VA3 passing through a geometrical center of a most proximal memory opening 49 within a most proximal even-numbered row is laterally offset from the first vertical axis VA1 along the first horizontal direction hd1 by a second lateral offset distance that equals p/2.

In the fifth configuration, the pattern of the memory openings 49 may have three directions of periodic repetitions. The first direction of periodic repetition DPR_1 can be the first horizontal direction hd1, and the pattern of the memory openings 49 may repeat along the first direction of periodic repetition DPR_1 with the uniform pitch p, which is the center-to-center distance between geometrical centers of a neighboring pair of memory openings 49 within any row of memory openings 49. The second direction of periodic repetition DPR_2 can be rotated along a first rotation direction (which may be anticlockwise or clockwise) from the first direction of periodic repetition DPR_1 by an angle π/3−α, which is less than π/3. The pattern of the memory openings 49 may be repeated at every row along the second direction of periodic repetition DPR_2. Thus, the repetition distance along the second direction of periodic repetition DPR_2 is halved in the fifth configuration compared to the repetition distance in the fourth configuration. The fourth direction of periodic repetition DPR_3 can be rotated along a second rotation direction (which is the opposite direction of the first rotation direction) from the opposite direction of the first direction of periodic repetition DPR_1 by an angle π/3+β, which is greater than π/3. The pattern of the memory openings 49 may be repeated at every row along the fourth direction of periodic repetition DPR_3. Thus, the repetition distance along the fourth direction of periodic repetition DPR_3 is halved in the fifth configuration compared to the repetition distance in the fourth configuration.

The fifth configuration of the array of memory openings 49 provides a horizontal direction providing a greater average lateral distance between neighboring pairs of memory openings 49. This horizontal direction is labeled as “direction of easy lateral diffusion,” and provides high-diffusivity diffusion paths during subsequent processing steps that are employed to isotropically etch the sacrificial material layers 42 to form laterally-extending cavities, and to conformally deposit at least one conductive material to form electrically conductive layers. In the illustrated example, the “direction of easy lateral diffusion” may be parallel to the fourth direction of periodic repetition DPR_3.

In one embodiment, the geometrical centers of the memory openings 49 in the fifth configuration of the memory array 49 may be located at lattice sites of a periodic, close-packed hexagonal array.

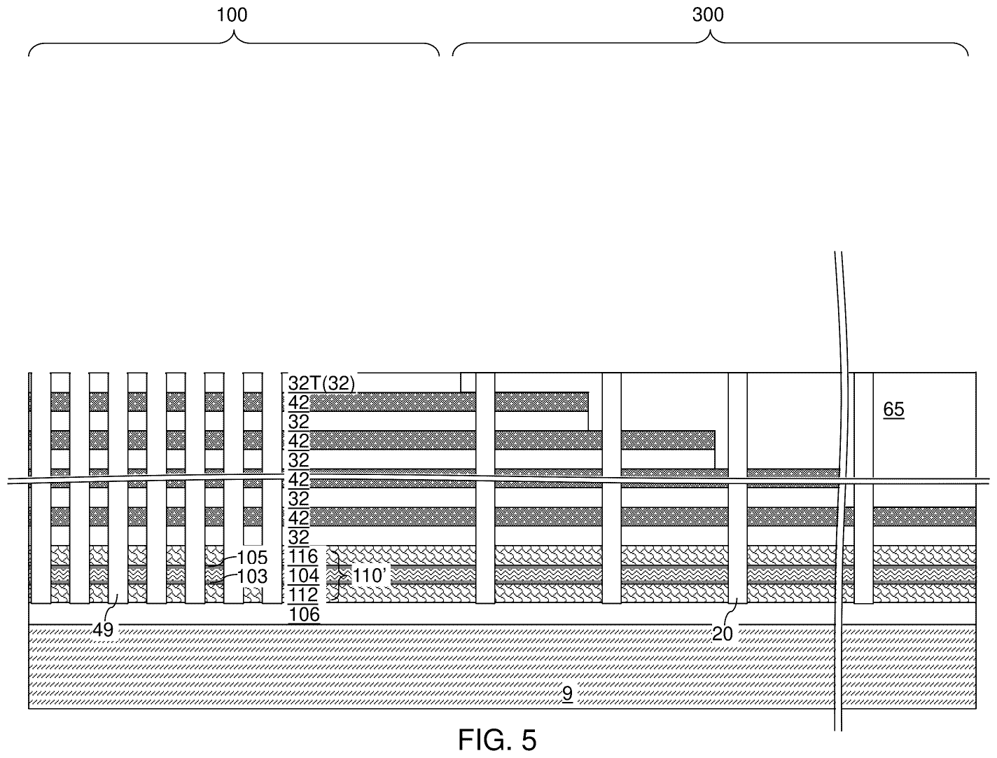

Referring to FIG. 5, an optional etch stop liner (not shown) and a sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 and the support openings 19 constitute sacrificial memory opening fill structures (not shown) and sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

A dielectric fill material, such as silicon oxide, can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

Subsequently, the sacrificial memory opening fill structures and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

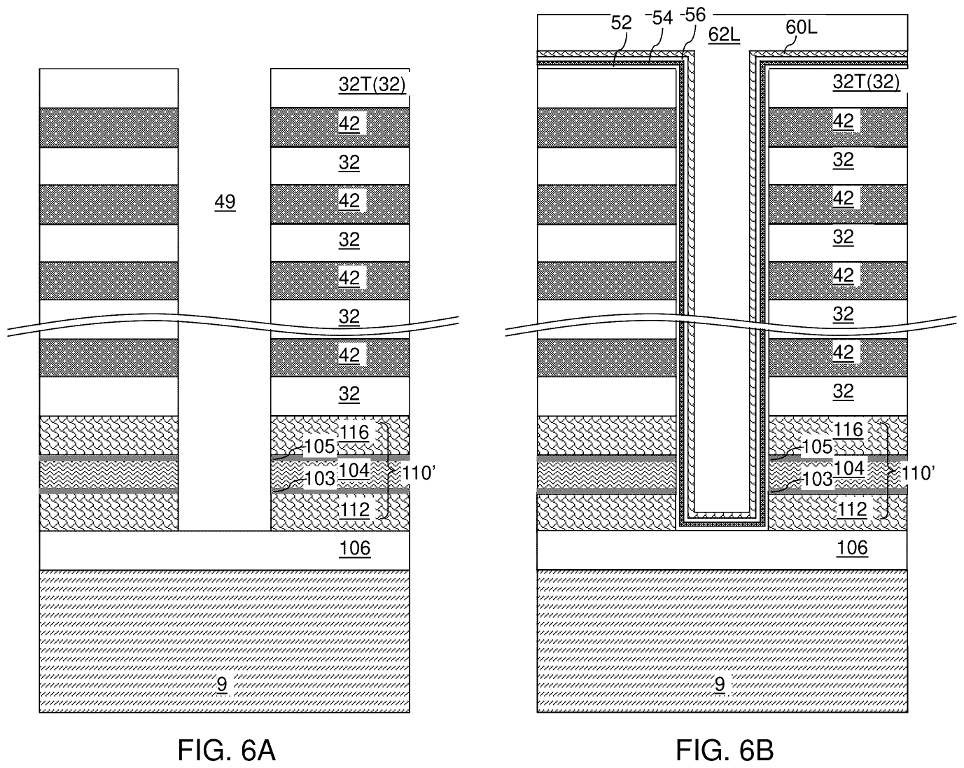

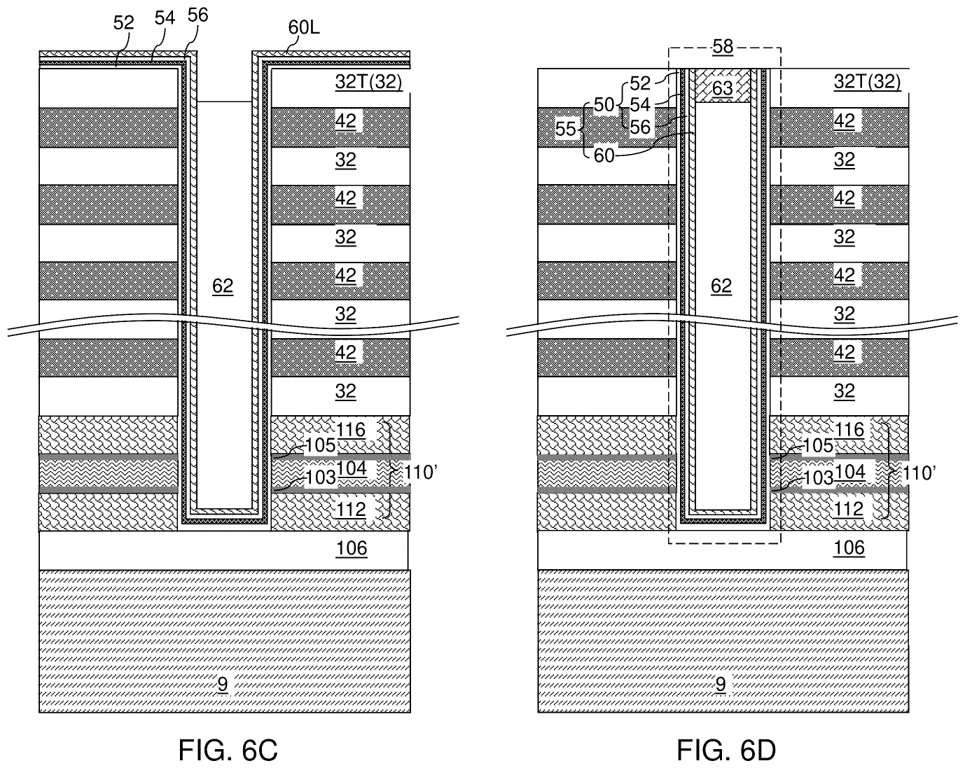

FIGS. 6A-6D are sequential schematic vertical cross-sectional views of a memory opening 49 within the exemplary structure during formation of a memory opening fill structure 58 according to an embodiment of the present disclosure.

Referring to FIG. 6A, a memory opening 49 is illustrated after the processing steps of FIG. 5.

Referring to FIG. 6B, a layer stack including a memory material layer 54 can be conformally deposited. In an illustrative example, the layer stack may comprise an optional blocking dielectric layer 52, the memory material layer 54, and an optional dielectric liner 56. The memory material layer 54 includes a memory material, i.e., a material that can store data bits therein. The memory material layer 54 may comprise a charge storage material (such as silicon nitride), a ferroelectric material, a phase change memory material, or any other memory material that can store data bits by inducing a change in the electrical resistivity, ferroelectric polarization, or any other measurable physical property. In case the memory material layer 54 comprise a charge storage material, the optional dielectric liner 56 may comprise a tunneling dielectric layer.

A semiconductor channel material layer 60L can be deposited over the layer stack (52, 54, 56) by performing a conformal deposition process. If the semiconductor channel material layer 60L is doped, the semiconductor channel material layer 60L may have a doping of a first conductivity type, which may be p-type or n-type. In one embodiment, the first semiconductor material comprises a first doped silicon material having a doping of the first conductivity type. In an illustrative example, the atomic concentration of dopants of the first conductivity type in the semiconductor channel material layer 60L may be in a range from 1.0×10¹³/cm³ to 3.0×10¹¹/cm³, such as 1.0×10¹⁴/cm³ to 3.0×10¹⁶/cm³, although lesser and greater atomic concentrations may also be employed. A dielectric core layer 62L comprising a dielectric fill material can be deposited in remaining volumes of the memory openings 49 and over the alternating stack (32, 42).

Referring to FIG. 6C, the dielectric core layer 62L can be vertically recessed such that each remaining portion of the dielectric core layer 62L has a top surface at, or about, the horizontal plane including the bottom surface of the topmost insulating layers 32T. Each remaining portion of the dielectric core layer 62L constitutes a dielectric core 62.

Referring to FIG. 6D, a doped semiconductor material having a doping of a second conductivity type can be deposited within each recessed region above the dielectric cores 62. The second conductivity type is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the topmost insulating layer 32T, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60.

Each portion of the layer stack including the memory material layer 54 that remains in a respective memory opening 49 constitutes a memory film 50. In one embodiment, a memory film 50 may comprise an optional blocking dielectric layer 52, a memory material layer 54, and an optional dielectric liner 56. Each contiguous combination of a memory film 50 and a vertical semiconductor channel 60 constitutes a memory stack structure 55. Each combination of a memory stack structure 55, a dielectric core 62, and a drain region 63 within a memory opening 49 constitutes a memory opening fill structure 58. Each memory opening fill structure 58 comprises a respective vertical stack of memory elements, which may comprise portions of the memory material layer 54 located at levels of the sacrificial material layers 42, or generally speaking, at levels of spacer material layers that may be formed as, or may be subsequently replaced at least partly with, electrically conductive layers.

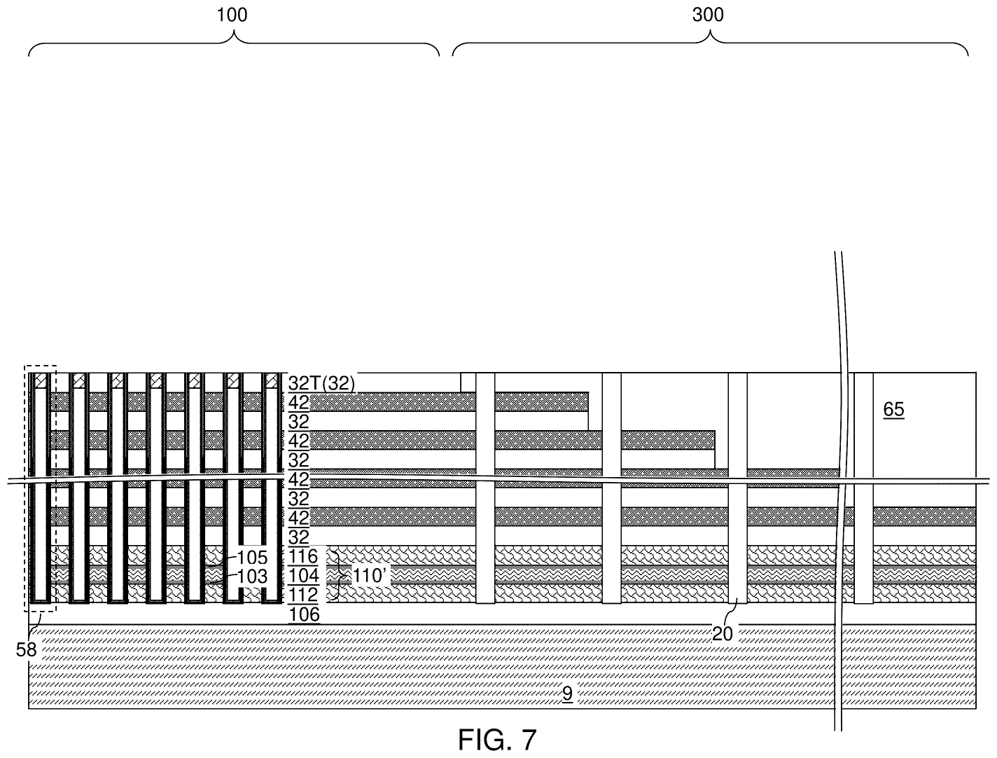

Referring to FIG. 7, the exemplary structure is illustrated after formation of memory opening fill structures 58 within the memory openings 49. Each of the memory opening fill structures 58 may comprise a respective vertical semiconductor channel 60 that is laterally surrounded by the respective vertical stack of memory elements (which may be embodied as portions of the memory film 50 located at levels of the sacrificial material layers 42 that are subsequently replaced with electrically conductive layers).

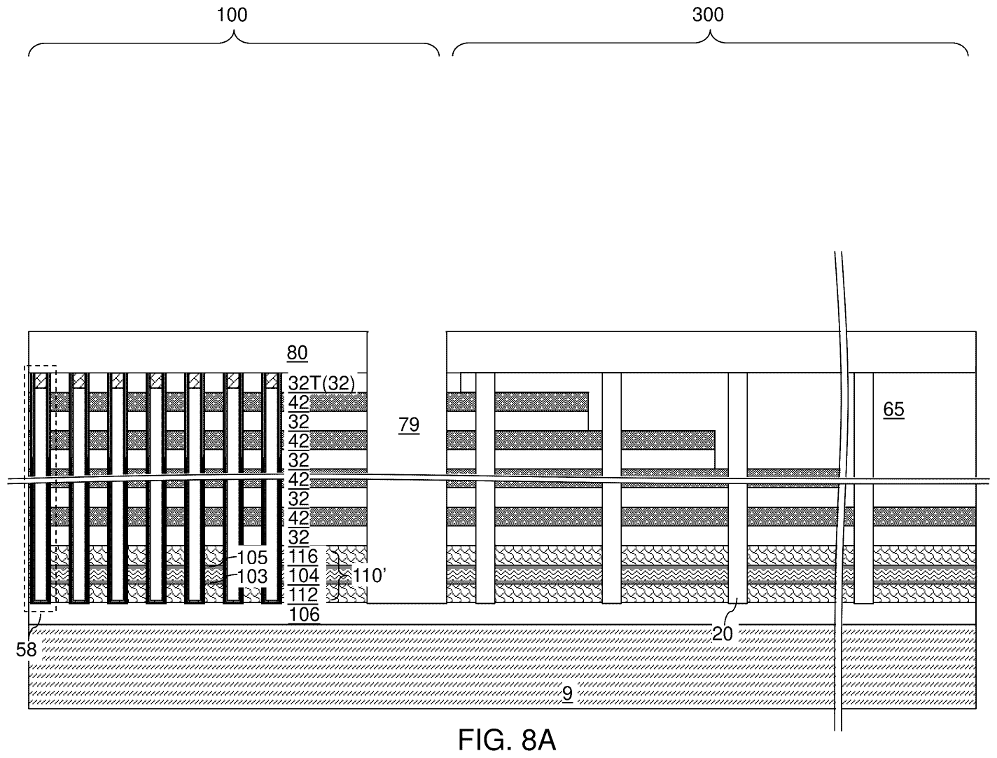

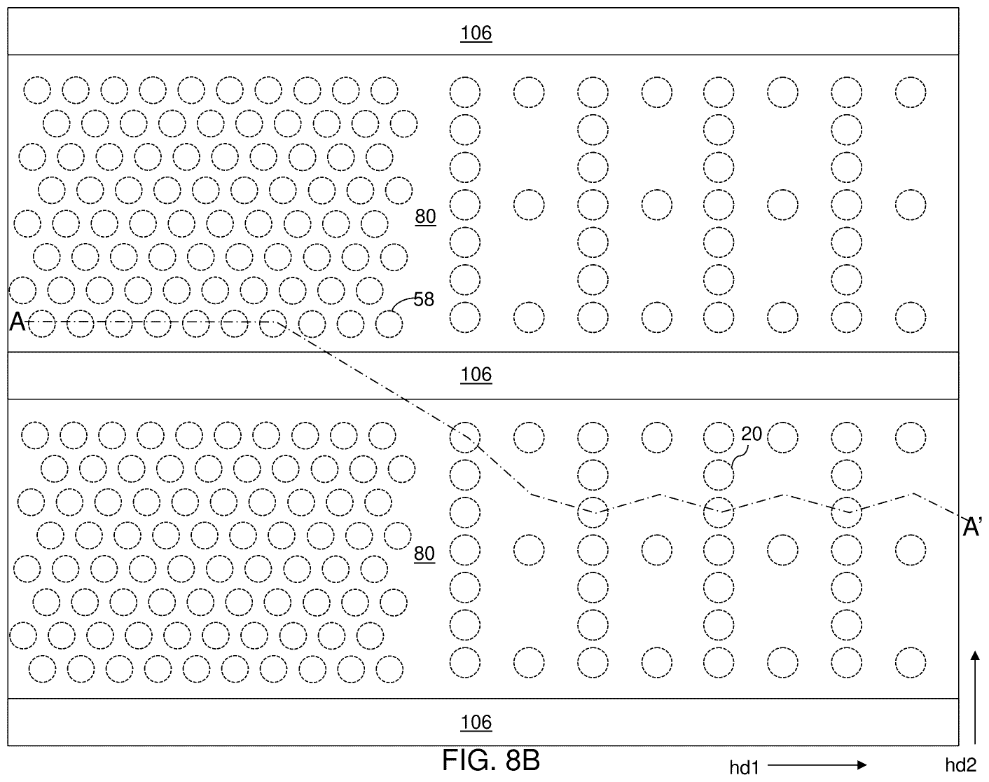

Referring to FIGS. 8A and 8B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the stepped dielectric material portion 65, and the in-process source-level material layers 110′. Lateral isolation trenches 79 laterally extending along the first horizontal direction hd1 can be formed through the alternating stack (32, 42), the stepped dielectric material portion 65, the contact-level dielectric layer 80, and the in-process source-level material layers 110′. Each of the lateral isolation trenches 79 may comprise a respective pair of lengthwise sidewalls that are parallel to the first horizontal direction hd1 and vertically extend from the stopper insulating layer 106 to the top surface of the contact-level dielectric layer 80. A top surface of the stopper insulating layer 106 can be physically exposed underneath each lateral isolation trench 79. The photoresist layer can be subsequently removed, for example, by ashing.

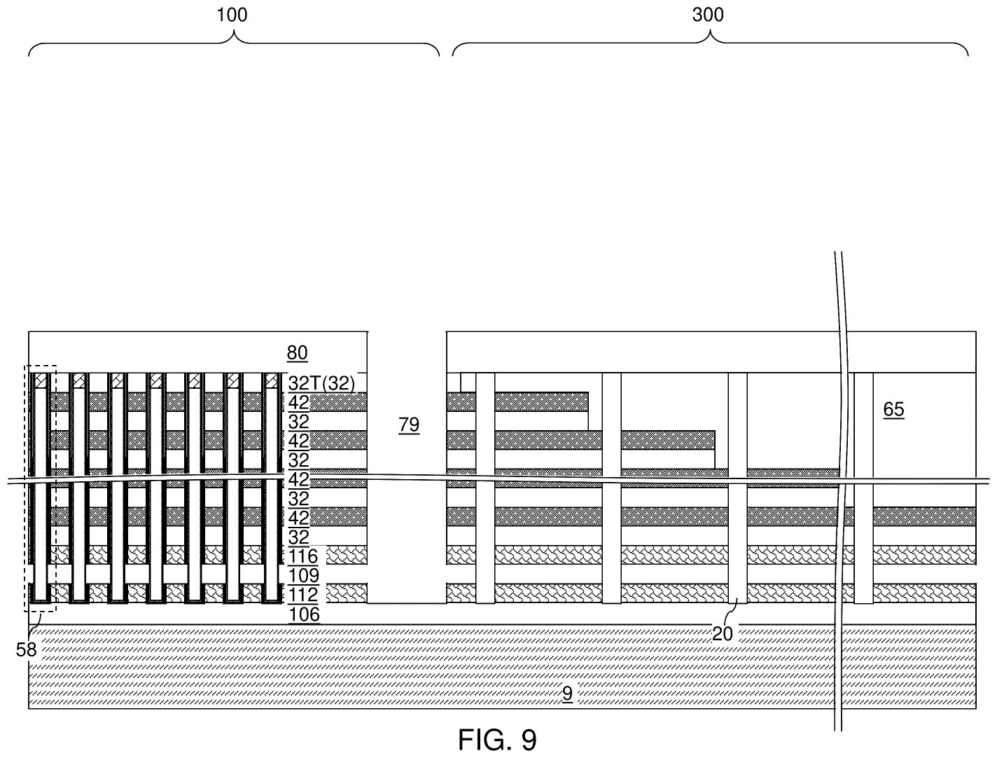

Referring to FIG. 9, an etchant that etches the material of the source-level sacrificial layer 104 selective to the materials of the alternating stack (32, 42), the contact level dielectric layer 80, the stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 includes undoped amorphous silicon or a silicon-germanium alloy, a wet etch process using hot trimethyl-2 hydroxyethyl ammonium hydroxide (“hot TMY”) or tetramethyl ammonium hydroxide (TMAH) may be used to remove the source-level sacrificial layer 104 selective to the alternating stack (32, 42), the contact level dielectric layer 80, the stepped dielectric material portion 65, the lower source-level semiconductor layer 112, and the upper source-level semiconductor layer 116. A source cavity 109 is formed in the volume from which the source-level sacrificial layer 104 is removed.

Wet etch chemicals such as hot TMY and TMAH are selective to doped semiconductor materials such as the p-doped semiconductor material and/or the n-doped semiconductor material of the upper source-level semiconductor layer 116 and the lower source-level semiconductor layer 112. Thus, use of selective wet etch chemicals such as hot TMY and TMAH for the wet etch process that forms the source cavity 109 provides a large process window against etch depth variation during formation of the lateral isolation trenches 79. Specifically, even if sidewalls of the upper source-level semiconductor layer 116 are physically exposed or even if a surface of the lower source-level semiconductor layer 112 is physically exposed upon formation of the source cavity 109, collateral etching of the upper source-level semiconductor layer 116 and/or the lower source-level semiconductor layer 112 is minimal, and the structural change to the exemplary structure caused by accidental physical exposure of the surfaces of the upper source-level semiconductor layer 116 and/or the lower source-level semiconductor layer 112 during manufacturing steps do not result in device failures. Each of the memory opening fill structures 58 is physically exposed to the source cavity 109. Specifically, each of the memory opening fill structures 58 includes a sidewall and that are physically exposed to the source cavity 109.

A sequence of isotropic etchants, such as wet etchants, may be applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109. The source cavity 109 may be expanded in volume by removal of the portions of the memory films 50 at the level of the source cavity 109 and the upper and lower sacrificial liners. A top surface of the lower source-level semiconductor layer 112 and a bottom surface of the upper source-level semiconductor layer 116 may be physically exposed to the source cavity 109. The source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

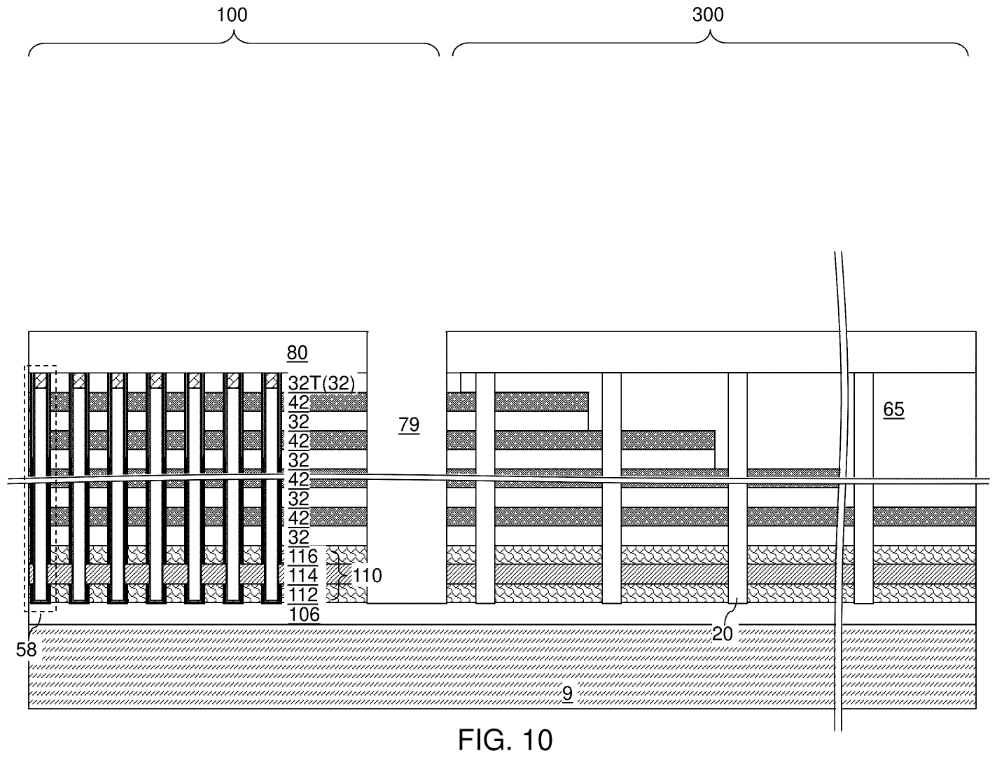

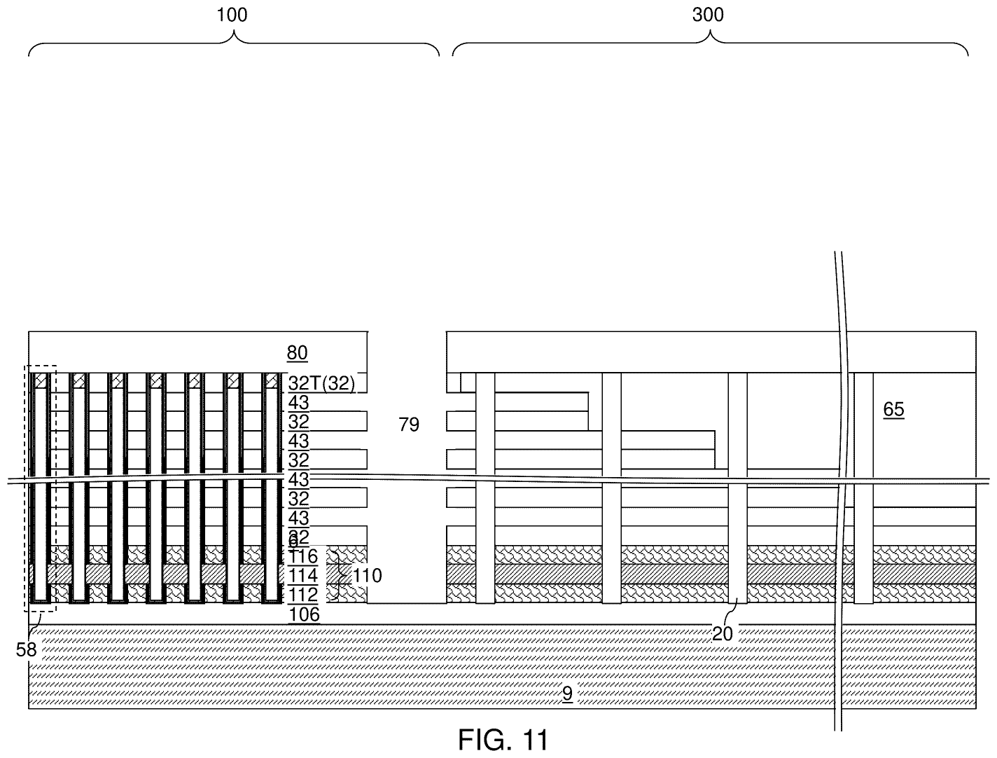

Referring to FIG. 10, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process. A semiconductor precursor gas, an etchant, and a dopant gas may be flowed concurrently into a process chamber including the exemplary structure during the selective semiconductor deposition process. For example, the semiconductor precursor gas may include silane, disilane, or dichlorosilane, the etchant gas may include gaseous hydrogen chloride, and the dopant gas may include a hydride of a dopant atom such as phosphine, arsine, stibine, or diborane. In this case, the selective semiconductor deposition process grows a doped semiconductor material having a doping of the second conductivity type from physically exposed semiconductor surfaces around the source cavity 109. The deposited doped semiconductor material forms a source contact layer 114, which may contact sidewalls of the vertical semiconductor channels 60. The atomic concentration of the dopants of the second conductivity type in the deposited semiconductor material may be in a range from 1.0×10²⁰/cm³ to 2.0×10²¹/cm³, such as from 2.0×10²⁰/cm³ to 8.0×10²⁰/cm³. The source contact layer 114 as initially formed may consist essentially of semiconductor atoms and dopant atoms of the second conductivity type. Alternatively, at least one non-selective doped semiconductor material deposition process may be used to form the source contact layer 114. Optionally, one or more etch back processes may be used in combination with a plurality of selective or non-selective deposition processes to provide a seamless and/or voidless source contact layer 114.

The duration of the selective semiconductor deposition process may be selected such that the source cavity 109 is filled with the source contact layer 114. In one embodiment, the source contact layer 114 may be formed by selectively depositing a doped semiconductor material having a doping of the second conductivity type from semiconductor surfaces around the source cavity 109. In one embodiment, the doped semiconductor material may include doped polysilicon. Thus, the source-level sacrificial layer 104 may be replaced with the source contact layer 114. The layer stack including the lower source-level semiconductor layer 112, the source contact layer 114, and the upper source-level semiconductor layer 116 constitutes a source layer 110, which replaces the in-process source-level material layers 110′. The source layer 110 contacts an end portion of each of the vertical semiconductor channels 60.

Referring to FIG. 11, an isotropic etch process can be performed to remove the sacrificial material layers 42 selective to the insulating layers 32, the stopper insulating layer 106, the memory opening fill structures 58, the sacrificial etch stop liners 71, and the source layer 110. According to an embodiment of the present disclosure, the presence of the direction of easy lateral diffusion (illustrated in FIGS. 4A-4I) facilitates lateral diffusion of the isotropic etchant during the isotropic etch process. Generally, the direction of easy lateral diffusion provides a greater lateral spacing between neighboring pairs of memory opening fill structures 58 than other lateral directions in the exemplary structure (such as the first direction of periodic repetition DPR_1 or the third direction of periodic repetition DPR_3). The greater lateral spacing among neighboring pairs of memory opening fill structures 58 along a horizontal direction that is perpendicular to the direction of easy lateral diffusion in the various embodiments of the present disclosure allows more effective lateral diffusion of the isotropic etchant during the isotropic etch process than a comparative exemplary structure employing a hexagonal periodic array of memory opening fill structures 58 having a respective circular horizontal cross-sectional shape (thereby not providing any direction of easy lateral diffusion). Thus, the various configurations of the present disclosure provide more effective etching of the sacrificial material layers 42.

Laterally-extending cavities 43 can be formed in volumes from which the sacrificial material layers 42 are removed. Sidewall surface segments of the memory opening fill structures 58 can be physically exposed to the laterally-extending cavities 43. In an illustrative example, if the sacrificial material layers 42 comprise silicon oxide, the isotropic etch process may comprise a wet etch process employing hot phosphoric acid, which is a process in which the exemplary structure is immersed in phosphoric acid at, or near, the boiling point of the phosphoric acid. A suitable clean process may be performed as needed.

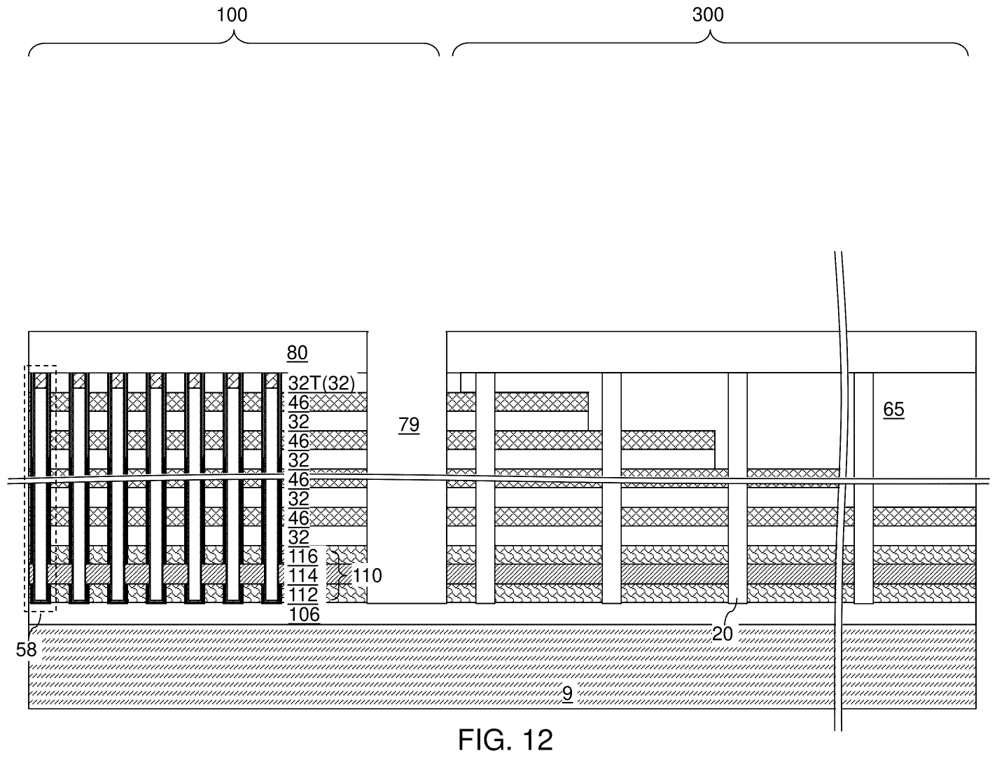

Referring to FIG. 12, a backside blocking dielectric layer (not shown) can be optionally formed in the laterally-extending cavities 43 by a conformal deposition process. At least one conductive material, such as at least one metallic material, can be conformally deposited in the laterally-extending cavities 43. At least one chemical vapor deposition process and/or at least one atomic layer deposition process can be employed to deposit the at least one conductive material. According to an embodiment of the present disclosure, the presence of the direction of easy lateral diffusion (illustrated in FIGS. 4A-4I) facilitates lateral diffusion of a reactant gas during the conformal deposition process(es). Generally, the direction of easy lateral diffusion provides a greater lateral spacing between neighboring pairs of memory opening fill structures 58 than other lateral directions in the exemplary structure (such as the first direction of periodic repetition DPR_1 or the third direction of periodic repetition DPR_3). The greater lateral spacing among neighboring pairs of memory opening fill structures 58 along a horizontal direction that is perpendicular to the direction of easy lateral diffusion in the various embodiments of the present disclosure allows more effective lateral diffusion of the reactant gas during each conformal deposition process than a comparative exemplary structure employing a hexagonal periodic array of memory opening fill structures 58 having a respective circular horizontal cross-sectional shape (thereby not providing any direction of easy lateral diffusion). Thus, the various configurations of the present disclosure provide more effective conformal deposition of the at least one conductive material while minimizing formation of any unfilled void.

The at least one conductive material may comprise, for example, a combination of a metallic barrier material and a metallic fill material. The metallic barrier material may comprise, for example, TiN, TaN, WN, MoN, TiC, TaC, WC, or a combination thereof. The metallic fill material may comprise, for example, Ti, Ta, Mo, Co, Ru, W, Cu, other transition metals, and/or alloys or layer stacks thereof. Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the carrier substrate 9. A plurality of alternating stacks of insulating layers 32 and electrically conductive layers 46 can be laterally spaced apart among one another by the lateral isolation trenches 79.

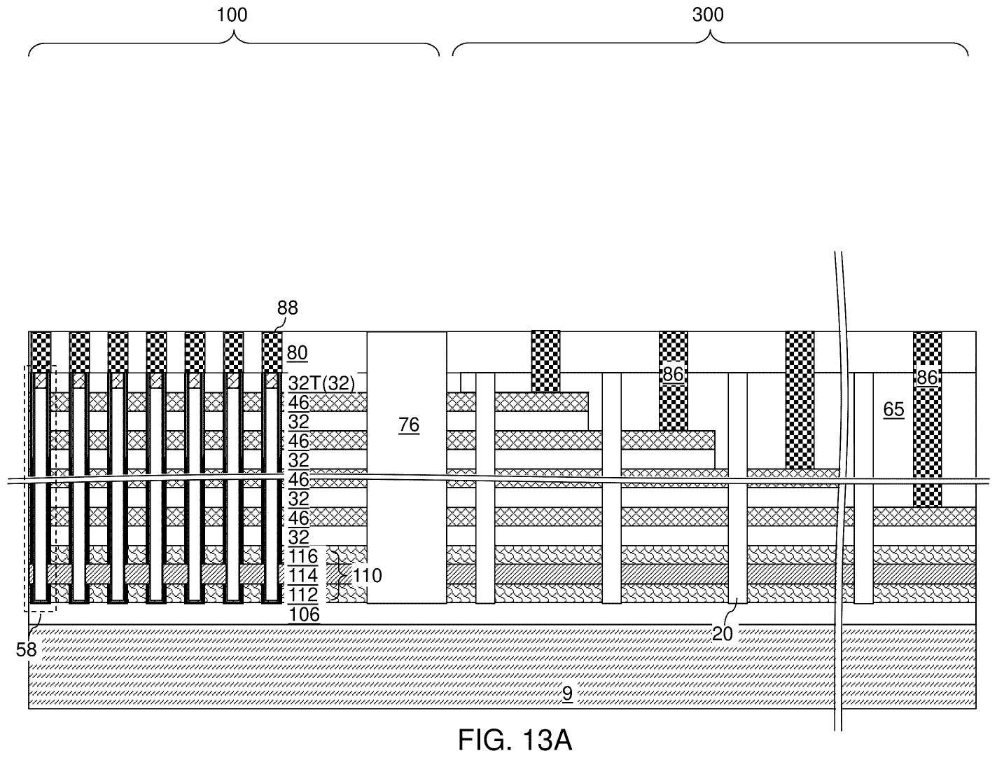

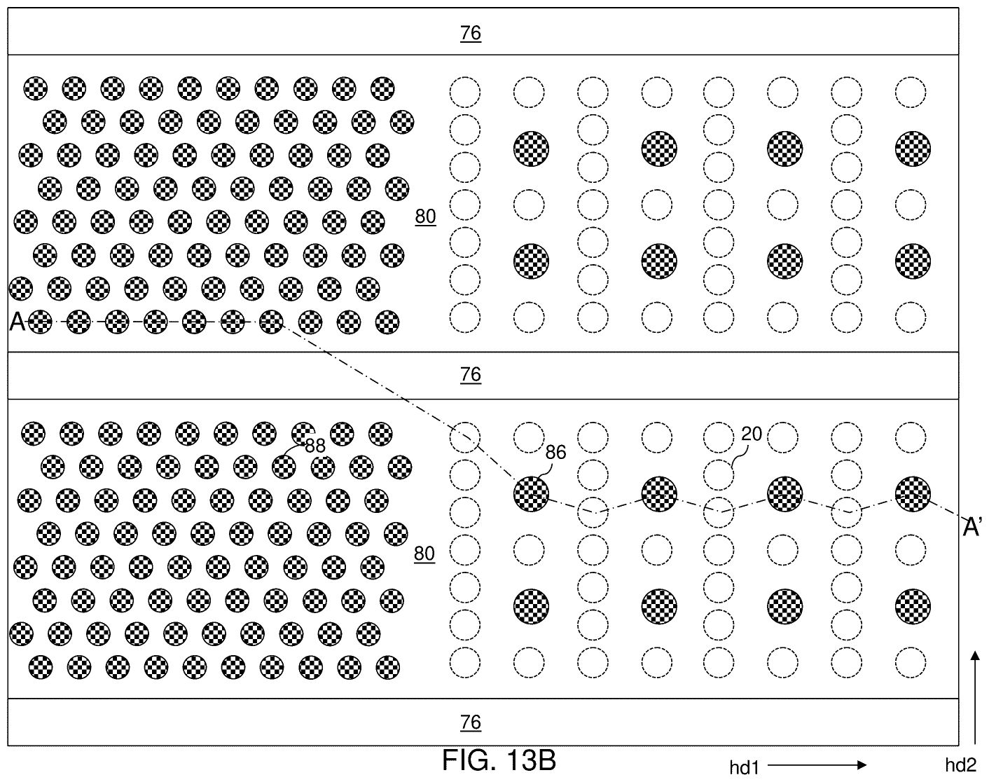

Referring to FIGS. 13A and 13B, an insulating fill material may be conformally deposited in the lateral isolation trenches 79. Excess portions of the insulating fill material may be removed from above the contact-level dielectric layer 80, for example, by a recess etch process. Each remaining portion of the insulating fill material that fills a respective lateral isolation trench 79 constitutes an isolation trench fill structure 76. Alternatively, each isolation trench fill structure 76 may comprise a combination of a tubular insulating spacer (not expressly shown) and a conductive connection via structure (not expressly shown) that is laterally surrounded by the tubular insulating spacer.

A photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

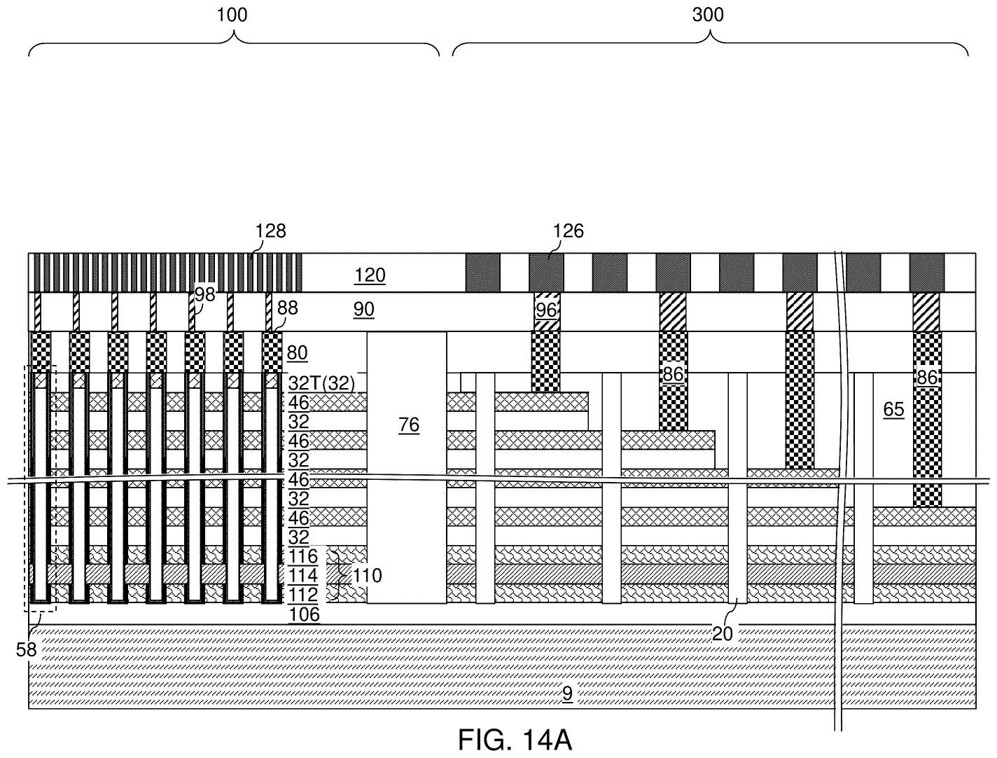

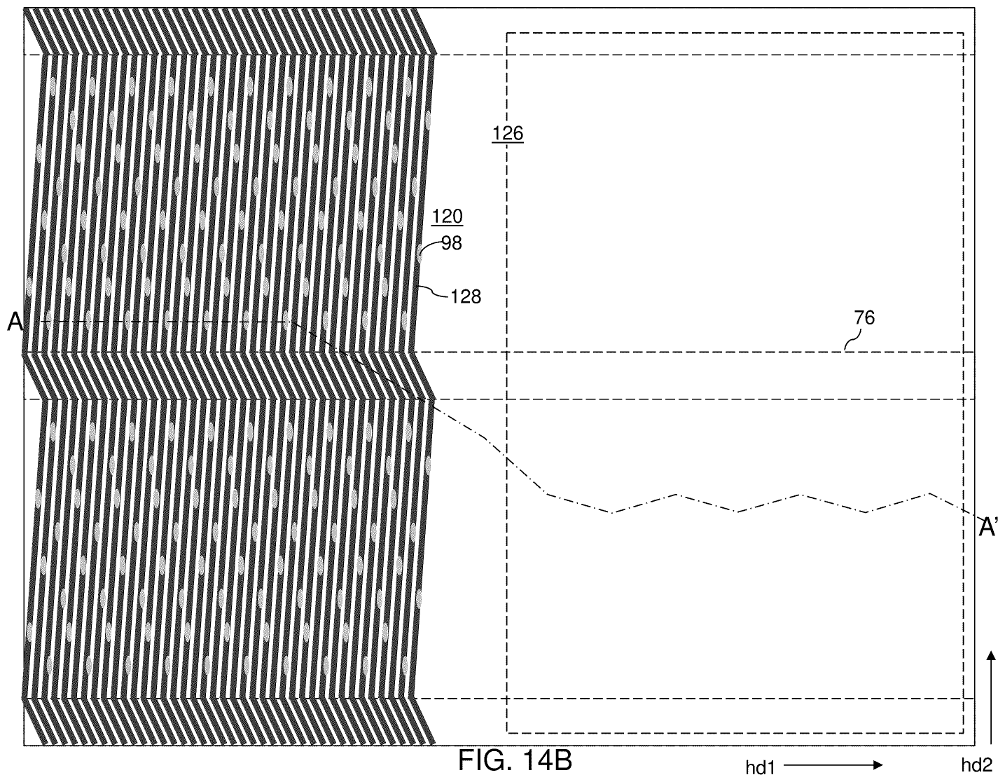

Referring to FIGS. 14A and 14B, a connection-level dielectric layer 90 can be formed above the contact-level dielectric layer 80. Connection via cavities can be formed through the connection-level dielectric layer 90, and can be filled with at least one conductive material (which may comprise at least one metallic material) to form connection-level via structures (98, 96). The connection-level via structures (98, 96) comprise drain connection via structures 98 that contact a respective one of the drain contact via structures 88, and layer connection via structures 96 that contact a respective one of the layer contact via structures 86.

A bit-line-level dielectric layer 120 can be formed above the connection-level dielectric layer 90. Bit-line-level line cavities can be formed through the bit-line-level dielectric layer 120, and can be filled with at least one conductive material (which may comprise at least one metallic material) to form bit-line-level metal lines (128, 126). The bit-line-level metal lines may comprise bit lines 128 that laterally extend generally along the second horizontal direction hd2 with periodic change of lateral extension directions such that the periodicity of the periodic change of the lateral extension directions is the same as the periodicity of the isolation trench fill structures 76. This feature can occur when the first lateral offset distance Δ is not equal to zero, as in the case of the first through fourth configurations of the arrays of memory openings 49 (and thus, of the arrays of memory opening fill structures 58) described above. In this case, the tilt angle of longer sections of the bit lines 128 relative to the second horizontal direction hd2 may be the arctangent of the ratio of the first lateral offset distance Δ to the center-to-center distance between neighboring pairs of even-numbered rows of memory openings 49 (which is the same as the center-to-center distance between neighboring pairs of even-numbered rows of memory opening fill structures 58).

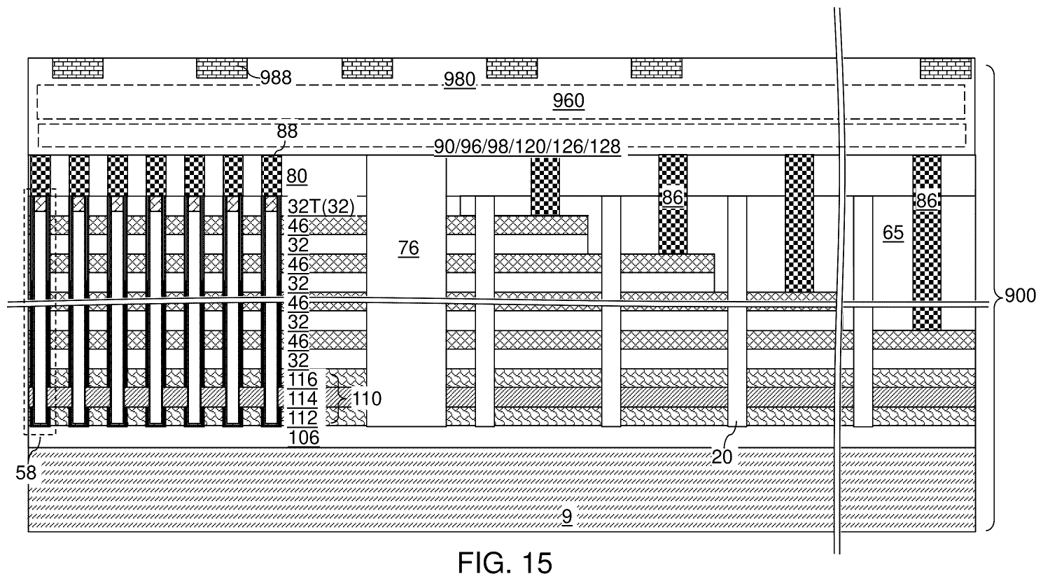

Referring to FIG. 15, additional dielectric material layers and additional metal interconnect structures can be formed over the bit-line-level dielectric layer 120. The additional dielectric material layers may include at least one via-level dielectric layer, at least one additional line-level dielectric layer, and/or at least one additional line-and-via-level dielectric layer. The additional metal interconnect structures may comprise metal via structures, metal line structures, and/or integrated metal line-and-via structures. The additional dielectric material layers that are formed above the bit-line-level dielectric layer 120 are herein referred to as memory-side dielectric material layers 960. The additional metal interconnect structures are collectively referred to as memory-side metal interconnect structures 980.

Metal bonding pads, which are herein referred to as upper bonding pads 988, may be formed at the topmost level of the memory-side dielectric material layers 960. The upper bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array underlying the first dielectric material layer 110 and comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

Generally speaking, a memory die 900 comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, the electrically conductive layers 46 comprise word lines of the two-dimensional array of NAND strings.

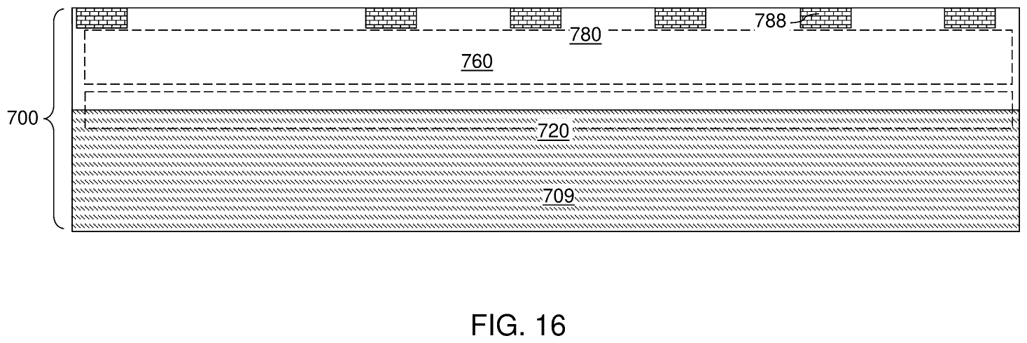

Referring to FIG. 16, a logic die 700 is provided. The logic die 700 comprises a peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

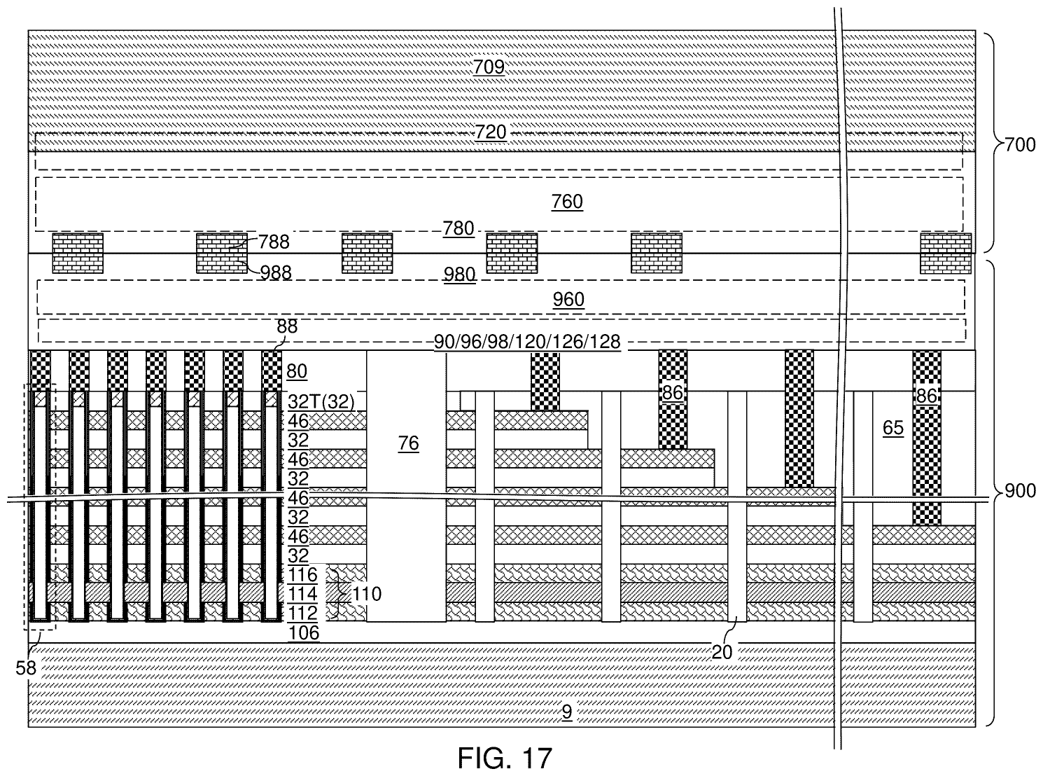

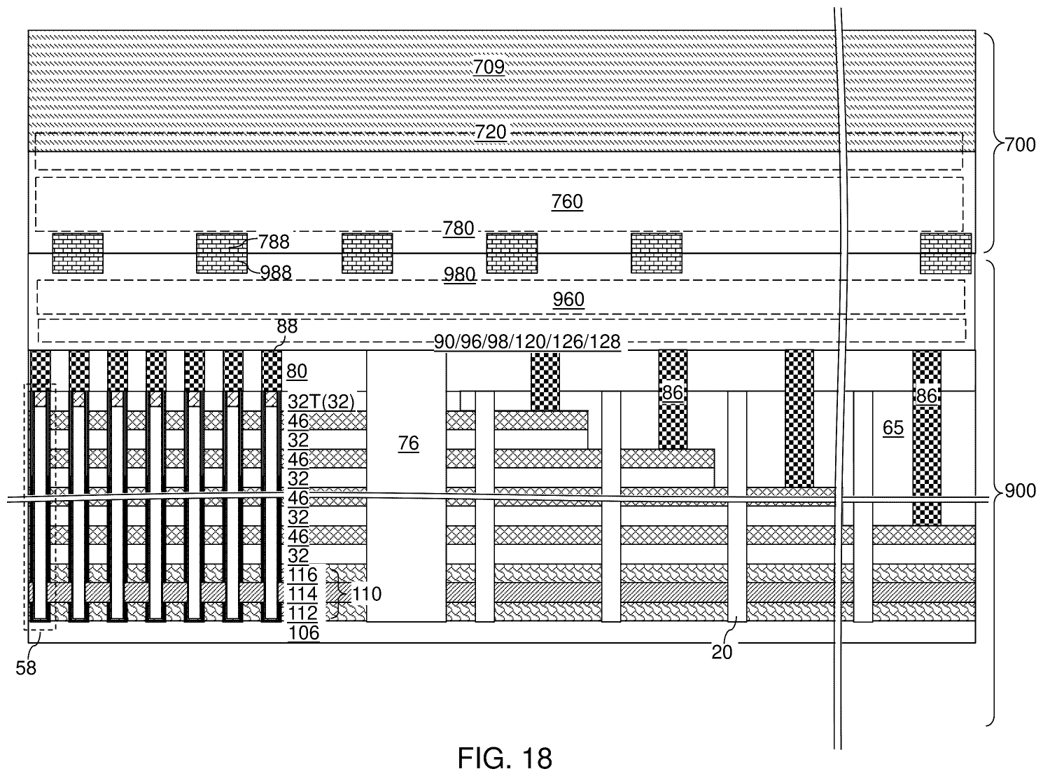

Referring to FIG. 17, a bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

Referring to FIG. 18, the carrier substrate 9 can be optionally removed, for example, by grinding, polishing, cleaving, an isotropic etch process, and/or an anisotropic etch process. If a polishing process such as a chemical mechanical polishing process is employed to remove the carrier substrate 9, the stopper insulating layer 106 may be subsequently employed as a polishing stopper material layer. If an etch process such as a wet etch process is employed to remove the carrier substrate 9, the stopper insulating layer 106 may be subsequently employed as an etch stop material layer.

Referring to all drawings and according to the first, second and third embodiments of the present disclosure, a memory device comprises: an alternating stack (32, 46) of insulating layers 32 and electrically conductive layers 46; memory openings 49 vertically extending through the alternating stack, wherein a smallest unit shape of three nearest neighbor memory openings is a non-equilateral triangle; and memory opening fill structures 58 located in the memory openings, wherein each of the memory opening fill structures comprises a vertical semiconductor channel 60 and a vertical stack of memory elements (e.g., portions of the memory film 50).

In one embodiment, the non-equilateral triangle comprises a scalene triangle.

In one embodiment, the memory openings 49 are arranged as multiple rows of memory openings. Each row of the multiple rows comprises a respective one-dimensional periodic array of memory openings 49 having a uniform pitch p along a first horizontal direction hd1, and the multiple rows are laterally spaced apart from each other along a second horizontal direction hd2 that is perpendicular to the first horizontal direction hd1, wherein the multiple rows comprise, upon sequentially numbering with integers beginning with 1 along the second horizontal direction hd2, odd-numbered rows and even-numbered rows, and wherein, for each first vertical axis VA1 passing through a geometrical center of a respective memory opening 49 in any odd-numbered row, a second vertical axis VA2 passing through a geometrical center of a most proximal memory opening 49 within a most proximal odd-numbered row is laterally offset from the first vertical axis VA1 along the first horizontal direction hd1 by a first lateral offset distance Δ that is greater than 0 and is less than one half of the uniform pitch p.

In one embodiment, for each first vertical axis VA1 passing through the geometrical center of the respective memory opening 49 in any odd-numbered row, a third vertical axis VA3 passing through a geometrical center of a most proximal memory opening 49 within a most proximal even-numbered row is laterally offset from the first vertical axis VA1 along the first horizontal direction hd1 by a second lateral offset distance (p−Δ)/2−η that is greater than 0 and is less than (p−Δ)/2. In one embodiment, a difference between said (p−Δ)/2 and the second lateral offset distance (p−Δ)/2−η is a lateral shift distance η that is greater than 0 and is less than Δ/2.

In one embodiment, for each first vertical axis VA1 passing through the geometrical center of the respective memory opening 49 in any odd-numbered row, a third vertical axis VA3 passing through a geometrical center of a most proximal memory opening 49 within a most proximal even-numbered row is laterally offset from the first vertical axis VA1 along the first horizontal direction hd1 by a second lateral offset distance that equals (p−Δ)/2.

In one embodiment, for each first vertical axis VA1 passing through the geometrical center of the respective memory opening 49 in any odd-numbered row, a planar vertical plane that passes through the first vertical axis VA1 and is parallel to the second horizontal direction hd2 does not pass through a geometrical center of any memory opening 49 within any nearest-neighboring row of memory openings 49 or within any second-nearest-neighboring row of memory openings 49.

In one embodiment, a first vertical plane VP1 passing through a geometrical center of a memory opening 49 within an odd-numbered row of memory openings 49 and passing through a geometrical center of a memory opening 49 within a nearest-neighboring odd-numbered row of memory openings 49 is at a first angle (π/3−α) with respective to the first horizontal direction hd1, wherein the first angle (π/3−α) is less than π/3 and is greater than arctan(\sqrt{3}/(1.5)). In one embodiment, a second vertical plane VP2 passing through the geometrical center of the memory opening 49 within the odd-numbered row of memory openings 49 and passing through a geometrical center of another memory opening 49 within the nearest-neighboring odd-numbered row of memory openings 49 is at a second angle (π/3+β) with respective to the first horizontal direction hd1, wherein the second angle (π/3+β) is greater than π/3 and is less than arctan(\sqrt{3}/(1.5)). In one embodiment, a third vertical plane VP3 passing through the geometrical center of the memory opening 49 within the odd-numbered row of memory openings 49 and passing through a geometrical center of a memory opening 49 a nearest-neighboring even-numbered row of memory openings 49 is at a third angle (π/3+γ) with respective to the first horizontal direction hd1, wherein the third angle (π/3+γ) is greater than the second angle (π/3+β).

In the first and second embodiments, each of the memory openings 49 has a respective circular horizontal cross-sectional shape. In the third embodiment, each of the memory openings 49 respective elongated horizontal cross-sectional shape having a respective major axis and a respective a minor axis. The major axes of the memory openings extend in a nearest neighbor memory opening direction.

According to the third and fourth embodiments, a memory device comprises: an alternating stack (32, 46) of insulating layers 32 and electrically conductive layers 46; memory openings 49 vertically extending through the alternating stack, wherein each of the memory openings 49 has a respective elongated horizontal cross-sectional shape having a respective a major axis and a respective minor axis, and the major axes of the memory openings extend in a nearest neighbor memory opening direction; and memory opening fill structures 58 located in the memory openings, wherein each of the memory opening fill structures comprises a vertical semiconductor channel 60 and a vertical stack of memory elements (e.g., portions of the memory film 50).

In one embodiment, the memory openings 49 are arranged as multiple rows of memory openings. Each row of the multiple rows comprises a respective one-dimensional periodic array of memory openings 49 having a uniform pitch p along a first horizontal direction hd1, and the multiple rows are laterally spaced from each other along a second horizontal direction hd2 that is perpendicular to the first horizontal direction hd1, and the major axes of the memory openings 49 are parallel to each other, and are at a non-zero and non-orthogonal angle with respect to the first horizontal direction hd1.

In one embodiment, the multiple rows comprise, upon sequentially numbering with integers beginning with 1 along the second horizontal direction hd2, odd-numbered rows and even-numbered rows; and each pattern of memory openings 49 in any odd-numbered row is periodically repeated in every other odd-numbered row along the second horizontal direction hd2 with a periodicity that equals a center-to-center distance between neighboring pairs of odd-numbered rows within the multiple rows.

In one embodiment, the multiple rows comprise, upon sequentially numbering with integers beginning with 1 along the second horizontal direction hd2, odd-numbered rows and even-numbered rows; and for each first vertical axis VA1 passing through a geometrical center of a respective memory opening 49 in any odd-numbered row, a second vertical axis VA2 passing through a geometrical center of a most proximal memory opening 49 within a most proximal odd-numbered row is laterally offset from the first vertical axis VA1 along the first horizontal direction hd1 by a first lateral offset distance Δ that is greater than 0 and is less than one half of the uniform pitch p. In one embodiment, the non-zero and non-orthogonal angle is greater than p/3 and is less than arctan(2\sqrt{3}).

In the third embodiment, a smallest unit shape of three nearest neighbor memory openings is a scalene triangle. In the fourth embodiment, a smallest unit shape of three nearest neighbor memory openings is an equilateral triangle.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A memory device, comprising:
an alternating stack of insulating layers and electrically conductive layers;
memory openings vertically extending through the alternating stack, wherein a smallest unit shape of three nearest neighbor memory openings is a non-equilateral triangle; and
memory opening fill structures located in the memory openings, wherein each of the memory opening fill structures comprises a vertical semiconductor channel and a vertical stack of memory elements.

2. The memory device of claim 1, wherein the non-equilateral triangle comprises a scalene triangle.

3. The memory device of claim 2, wherein:
the memory openings are arranged as multiple rows of memory openings;
each row of the multiple rows comprises a respective one-dimensional periodic array of memory openings having a uniform pitch p along a first horizontal direction, and the multiple rows are laterally spaced apart from each other along a second horizontal direction that is perpendicular to the first horizontal direction;
the multiple rows comprise, upon sequentially numbering with integers beginning with 1 along the second horizontal direction, odd-numbered rows and even-numbered rows, and wherein, for each first vertical axis passing through a geometrical center of a respective memory opening in any odd-numbered row, a second vertical axis passing through a geometrical center of a most proximal memory opening within a most proximal odd-numbered row is laterally offset from the first vertical axis along the first horizontal direction by a first lateral offset distance Δ that is greater than 0 and is less than one half of the uniform pitch p.

4. The memory device of claim 3, wherein, for each first vertical axis passing through the geometrical center of the respective memory opening in any odd-numbered row, a third vertical axis passing through a geometrical center of a most proximal memory opening within a most proximal even-numbered row is laterally offset from the first vertical axis along the first horizontal direction by a second lateral offset distance (p−Δ)/2−η that is greater than 0 and is less than (p−Δ)/2.

5. The memory device of claim 4, wherein a difference between said (p−Δ)/2 and the second lateral offset distance (p−Δ)/2−η is a lateral shift distance η that is greater than 0 and is less than Δ/2.

6. The memory device of claim 3, wherein, for each first vertical axis passing through the geometrical center of the respective memory opening in any odd-numbered row, a third vertical axis passing through a geometrical center of a most proximal memory opening within a most proximal even-numbered row is laterally offset from the first vertical axis along the first horizontal direction by a second lateral offset distance that equals (p−Δ)/2.

7. The memory device of claim 3, wherein, for each first vertical axis passing through the geometrical center of the respective memory opening in any odd-numbered row, a planar vertical plane that passes through the first vertical axis and is parallel to the second horizontal direction does not pass through a geometrical center of any memory opening within any nearest-neighboring row of memory openings or within any second-nearest-neighboring row of memory openings.

8. The memory device of claim 3, wherein a first vertical plane passing through a geometrical center of a memory opening within an odd-numbered row of memory openings and passing through a geometrical center of a memory opening within a nearest-neighboring odd-numbered row of memory openings is at a first angle (π/3−α) with respective to the first horizontal direction, wherein the first angle (π/3−α) is less than π/3 and is greater than arctan(\sqrt{3}/(1.5)).

9. The memory device of claim 8, wherein a second vertical plane passing through the geometrical center of the memory opening within the odd-numbered row of memory openings and passing through a geometrical center of another memory opening within the nearest-neighboring odd-numbered row of memory openings is at a second angle (π/3+β) with respective to the first horizontal direction, wherein the second angle (π/3+β) is greater than π/3 and is less than arctan(\sqrt{3}/(1.5)).

10. The memory device of claim 8, wherein a third vertical plane passing through the geometrical center of the memory opening within the odd-numbered row of memory openings and passing through a geometrical center of a memory opening in a nearest-neighboring even-numbered row of memory openings is at a third angle (π/3+γ) with respective to the first horizontal direction, wherein the third angle (π/3+γ) is greater than the second angle (π/3+β).

11. The memory device of claim 1, wherein each of the memory openings has a respective circular horizontal cross-sectional shape.

12. The memory device of claim 1, wherein:
each of the memory openings has a respective elongated horizontal cross-sectional shape having a respective a major axis and a respective minor axis; and
the major axes of the memory openings extend in a nearest neighbor memory opening direction.

13. A memory device, comprising:
an alternating stack of insulating layers and electrically conductive layers;
memory openings vertically extending through the alternating stack, wherein each of the memory openings has a respective elongated horizontal cross-sectional shape having a respective a major axis and a respective minor axis, and the major axes of the memory openings extend in a nearest neighbor memory opening direction; and
memory opening fill structures located in the memory openings, wherein each of the memory opening fill structures comprises a vertical semiconductor channel and a vertical stack of memory elements.

14. The memory device of claim 13, wherein:
the memory openings are arranged as multiple rows of memory openings;
each row of the multiple rows comprises a respective one-dimensional periodic array of memory openings having a uniform pitch p along a first horizontal direction and the multiple rows are laterally spaced from each other along a second horizontal direction that is perpendicular to the first horizontal direction; and
the major axes of the memory openings are parallel to each other, and are at a non-zero and non-orthogonal angle with respect to the first horizontal direction.

15. The memory device of claim 14, wherein:
the multiple rows comprise, upon sequentially numbering with integers beginning with 1 along the second horizontal direction, odd-numbered rows and even-numbered rows; and
each pattern of memory openings in any odd-numbered row is periodically repeated in every other odd-numbered row along the second horizontal direction with a periodicity that equals a center-to-center distance between neighboring pairs of odd-numbered rows within the multiple rows.

16. The memory device of claim 14, wherein:
the multiple rows comprise, upon sequentially numbering with integers beginning with 1 along the second horizontal direction, odd-numbered rows and even-numbered rows; and
for each first vertical axis passing through a geometrical center of a respective memory opening in any odd-numbered row, a second vertical axis passing through a geometrical center of a most proximal memory opening within a most proximal odd-numbered row is laterally offset from the first vertical axis along the first horizontal direction by a first lateral offset distance Δ that is greater than 0 and is less than one half of the uniform pitch p.

17. The memory device of claim 13, wherein a smallest unit shape of three nearest neighbor memory openings is a scalene triangle.

18. The memory device of claim 13, wherein a smallest unit shape of three nearest neighbor memory openings is an equilateral triangle.

19. A method of forming a memory device, comprising:
forming an alternating stack of insulating layers and sacrificial material layers over a substrate;
forming memory openings vertically extending through the alternating stack, wherein a smallest unit shape of three nearest neighbor memory openings is a non-equilateral triangle;
forming memory opening fill structures located in the memory openings, wherein each of the memory opening fill structures comprises a respective vertical stack of memory elements and vertical semiconductor channels;
removing the sacrificial material layers from between the memory opening fill structures to form laterally-extending cavities; and
forming electrically conductive layers in the laterally extending cavities.

20. The method of claim 19, wherein:
the non-equilateral triangle comprises a scalene triangle; and
a first diffusion path is provided in the laterally extending cavities between a first set of memory openings which is wider than a second diffusion path provided in the laterally-extending cavities between a second set of memory openings.
